(19) United States
(12) Patent Application Publication
(10) Pub. No.: US 2026/0114164 A1
(43) Pub. Date: Apr. 23, 2026

(54) ELECTRONIC DEVICE

(71) Applicant: Samsung Display Co., Ltd., Yongin-si (KR)

(72) Inventors: SOODONG KIM, Yongin-si (KR); JUNGHWAN YI, Yongin-si (KR); REEHYANG KIM, Yongin-si (KR); YUNHA RYU, Yongin-si (KR); JUNHYUK WOO, Yongin-si (KR)

(21) Appl. No.: 19/292,784

(22) Filed: Aug. 6, 2025

(30) Foreign Application Priority Data
Oct. 21, 2024 (KR) 10-2024-0143624

(51) Int. Cl. H10K 59/80; H10K 59/12; H10K 59/122; H10K 59/38; H10K 102/00

(52) U.S. Cl. CPC H10K 59/879; H10K 59/1201; H10K 59/122; H10K 59/38; H10K 2102/351

(57) ABSTRACT

An electronic device and a method for manufacturing the electronic device are disclosed. The electronic device may include a first base substrate, a second base substrate on the first base substrate, a filling layer between the first base substrate and the second base substrate, a pixel definition film that defines a first light emission area, a second light emission area, and a third light emission area that emit different lights and a non-light emission area, a plurality of light emitting elements, a light control layer arranged on the non-light emission area and including partition walls, in which openings that correspond to the first to third light emission areas may be defined, and a plurality of light control components arranged in the openings, respectively, a plurality of column patterns, and a low-refraction layer.

### CROSS-REFERENCE TO RELATED APPLICATION

The present application claims priority to and the benefit of Korean Patent Application No. 10-2024-0143624, filed on Oct. 21, 2024, in the Korean Intellectual Property Office, the entire disclosure of which is incorporated herein by reference.

### BACKGROUND

### 1. Field

One or more embodiments of the present disclosure relate to an electronic device, and, for example, relate to an electronic device with improved or enhanced optical properties.

### 2. Description of the Related Art

Electronic devices include a transmissive electronic device that selectively transmits a source light generated from a light source and a light emitting electronic device that generates a source light in the electronic device itself. The electronic devices may include different types (kinds) of light control components depending on pixels to generate an image. The light control component may be to transmit a partial wavelength range of the source light or may convert a color of the source light.

To improve or enhance an optical reliability of electronic devices, researches are being conducted on an optical layer including a plurality of layers having different reflective indexes.

### SUMMARY

One or more aspects of embodiments of the present disclosure are directed toward an electronic device with improved or enhanced optical properties.

Additional aspects of embodiments will be set forth in part in the description which follows and, in part, will be apparent from the description or may be learned by practice of the presented embodiments of the disclosure.

According to one or more embodiments, an electronic device includes a first base substrate, a second base substrate arranged on the first base substrate, a filling layer arranged between the first base substrate and the second base substrate, a pixel definition film that is arranged between the first base substrate and the filling layer and that defines a first light emission area, a second light emission area, and a third light emission area that are arranged to emit different lights and a non-light emission area being adjacent to the first light emission area, the second light emission area, and the third light emission area, a plurality of light emitting elements arranged in the first light emission area, the second light emission area, and the third light emission area, respectively, a light control layer arranged on the non-light emission area and including partition walls, in which openings that correspond to the first light emission area, the second light emission area, and the third light emission area may be defined, and a plurality of light control components arranged in the openings, respectively, and each of the plurality of light control components includes a quantum dot, a plurality of column patterns that overlap the first light emission area, the second light emission area, and the third light emission area, respectively, and a low-refraction layer arranged between the plurality of column patterns and the light control layer, and one selected from among the plurality of column patterns overlaps the first light emission area and the second light emission area.

On a plane (e.g., in plan view), an area of each of the plurality of column patterns may be greater than an area of each of the first light emission area, the second light emission area, and the third light emission area, and at least a portion of each of the plurality of column patterns may overlap the pixel definition film, on the plane.

The low-refraction layer may have an integral shape (e.g., a substantially integral shape).

Thicknesses of the plurality of column patterns may be smaller than a thickness of the filling layer.

Recessed parts may be defined on lower surfaces of the plurality of column patterns, respectively, and the low-refraction layer may include a plurality of low-refraction patterns spaced and/or apart (e.g., spaced apart or separated) from each other and be arranged in the recessed parts, respectively.

On a plane (e.g., in plan view), an area of each of the recessed parts may be greater than an area of each of the first light emission area, the second light emission area, and the third light emission area, and at least a portion of each of the recessed parts may overlap the pixel definition film, on the plane.

Thicknesses of the plurality of low-refraction patterns may be about 2 μm or less.

A refractive index of the low-refraction layer may be smaller than refractive indexes of the plurality of column patterns.

The electronic device may further include a color filter layer arranged on the plurality of column patterns and including a color filter.

The plurality of light emitting elements may include a first light emission area that is to emit a blue light, a second light emission area that is to emit a green light, and a third light emission area that is to emit a red light, and the plurality of column patterns may not overlap the first light emission area on a plane (e.g., in plan view).

According to one or more embodiments, an electronic device includes a display substrate, an optical substrate arranged on the display substrate, and a filling layer arranged between the display substrate and the optical substrate, the display substrate includes a pixel definition film that defines a plurality of light emission areas and non-light emission areas being adjacent to the plurality of light emission areas, a plurality of light emitting elements arranged in the plurality of light emission areas, respectively, partition walls arranged on the non-light emission areas and including openings that correspond to the plurality of light emission areas, and a plurality of light control components arranged in the partition walls, respectively, and including a quantum dot, the optical substrate includes a plurality of column patterns that overlap the non-light emission areas, and a plurality of low-refraction patterns arranged between two adjacent ones selected from among the plurality of column patterns and spaced and/or apart (e.g., spaced apart or separated) from each other, and at least portions of the plurality of low-refraction patterns overlap the plurality of light emission areas on a plane (e.g., in plan view).

Thicknesses of the plurality of low-refraction patterns may be smaller than a thickness of the filling layer.

Refractive indexes of the plurality of low-refraction patterns may be smaller than refractive indexes of the plurality of column patterns.

According to one or more embodiments, a method for manufacturing an electronic device includes providing a base member, forming or applying a column layer on the base member, forming a plurality of column patterns spaced and/or apart (e.g., spaced apart or separated) from each other, by patterning the column layer, forming or applying a low-refraction layer on the plurality of column patterns, providing a display substrate including a first light emission element, a second light emission element, and a third light emission element that are arranged to emit different lights, arranging the display substrate such that the first light emission element, the second light emission element, and the third light emission element and the low-refraction layer are opposite to (e.g., face) each other, and forming or applying a filling layer between the low-refraction layer and the display substrate, and one selected from among the plurality of column patterns overlaps the first light emitting element and the second light emitting element.

Entire (e.g., substantially entire) surfaces of the plurality of column patterns may be coated to form the low-refraction layer.

Recessed parts may be formed or arranged on upper surfaces of the plurality of column patterns by utilizing a half-tone mask.

Depths of the recessed parts may be about 2 μm or less.

The low-refraction layer may include a plurality of low-refraction patterns spaced and/or apart (e.g., spaced apart or separated) from each other, and the plurality of low-refraction patterns may be formed in the recessed parts, respectively.

The plurality of low-refraction patterns may be formed through an ink-jet printing process.

The method may further include combining the low-refraction layer and the display substrate.

### BRIEF DESCRIPTION OF THE DRAWINGS

The above and other aspects and features of certain embodiments of the present disclosure will become apparent and more readily appreciated from the following description of one or more embodiments, taken in conjunction with the accompanying drawings.

FIG. 1 is a perspective view of an electronic device according to one or more embodiments of the present disclosure.

FIG. 2 is a cross-sectional view of an electronic device according to one or more embodiments of the present disclosure.

FIG. 3 is a plan view of a partial area of an electronic device according to one or more embodiments of the present disclosure.

FIG. 4 is a cross-sectional view of an electronic device according to one or more embodiments of the present disclosure.

FIG. 5 is a plan view of a partial area of an electronic device according to one or more embodiments of the present disclosure.

FIG. 6 is a cross-sectional view of an electronic device according to one or more embodiments of the present disclosure.

FIG. 7 is a plan view of a partial area of an electronic device according to one or more embodiments of the present disclosure.

FIG. 8 is a cross-sectional view of an electronic device according to one or more embodiments of the present disclosure.

FIG. 9 is a cross-sectional view of an electronic device according to one or more embodiments of the present disclosure.

FIG. 10 is a block diagram illustrating a manufacturing sequence of an electronic device according to one or more embodiments of the present disclosure.

FIGS. 11A-11G are cross-sectional views illustrating one or more operations of a method for manufacturing an electronic device according to one or more embodiments of the present disclosure.

FIGS. 12A-12D are cross-sectional views illustrating one or more operations of a method for manufacturing an electronic device according to one or more embodiments of the present disclosure.

FIGS. 13A-13D are cross-sectional views illustrating one or more operations of a method for manufacturing an electronic device according to one or more embodiments of the present disclosure.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the present disclosure.

In the present disclosure, the expression that a first component (or an area, a layer, a part, and/or the like) is “on”, “connected with”, or “coupled with” a second component refers to that the first component may be “directly on,” “directly connected with,” or “directly coupled with” the second component or refers to that a third component may be present therebetween. In contrast, if (e.g., when) a first component is referred to as being “directly on,” “directly connected with,” or “directly coupled with” a second component, there may be no intervening components present therebetween.

The same reference numerals refer to substantially the same components. Also, in drawings, the thickness, ratio, and dimension of components may be exaggerated for effectiveness of description of technical contents.

The term “and/or” includes one or more combinations in each of which associated elements are defined.

Although the terms “first,” “second,” and/or the like may be used to describe one or more suitable components, the components should not be construed as being limited by the terms. The terms are only used to distinguish one component from another component. For example, without departing from the scope and spirit of the present disclosure, a first component may be referred to as a second component, and similarly, the second component may be referred to as the first component.

The articles “a,” “an,” and “the” are singular in that they have a single referent, but the use of the singular form in the present disclosure should not preclude the presence of more than one referent.

Also, the terms “under,” “below,” “on,” “above,” and/or the like are used to describe the correlation of components illustrated in drawings. The terms are relative concepts and are described with respect to directions indicated in the drawings.

It will be understood that the terms “include,” “including,” “have,” “having,” and/or the like specify the presence of features, numbers, steps (e.g., acts or tasks), operations, elements, or components, as described in the present disclosure, and/or a (e.g., any suitable) combination thereof, not precluding the presence or additional possibility of one or more other features, numbers, steps (e.g., acts or tasks), operations, elements, or components and/or a (e.g., any suitable) combination thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The utilization of “may” if (e.g., when) describing one or more embodiments of the present disclosure refers to “one or more embodiments of the present disclosure.”

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein, is inclusive of the stated value and refers to being within an acceptable range of deviation for the particular value as determined by one of ordinary skill in the art, considering the measurement in question and the error associated with measurement of the particular quantity (i.e., the limitations of the measurement system). For example, “about” may refer to being within one or more standard deviations, or within ±30%, ±20%, ±10%, or ±5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical terms and scientific terms) used in the present disclosure have substantially the same meaning as commonly understood by one skilled in the art to which the present disclosure belongs. Furthermore, the terms, such as the terms defined in dictionaries, which are generally used, should be construed to coincide with the context meanings of the related technologies and are not construed as ideal or excessively (or substantially) formal meanings unless explicitly defined in the present disclosure.

Hereinafter, one or more embodiments of the present disclosure will be described in more detail with reference to the accompanying drawings.

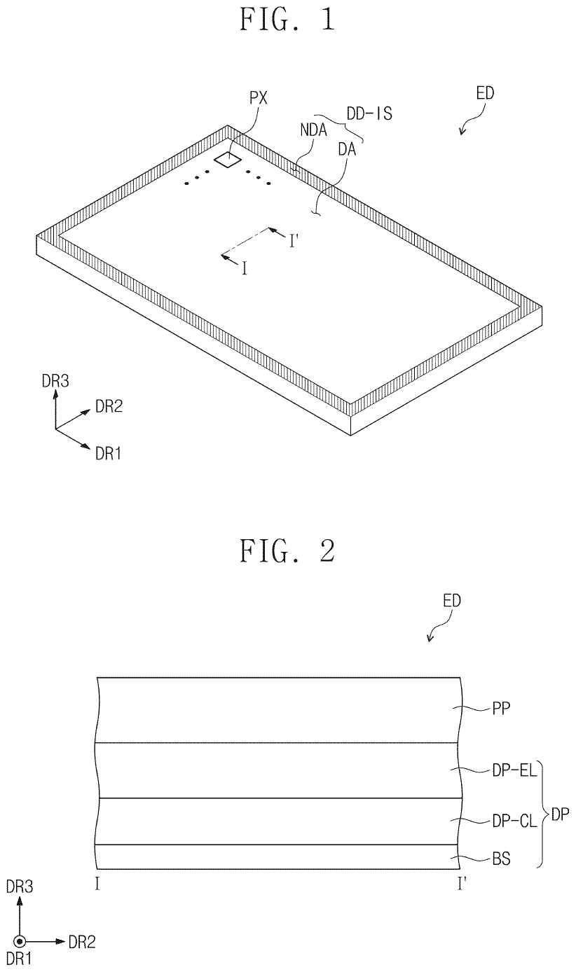

FIG. 1 is a perspective view of an electronic device according to one or more embodiments of the present disclosure.

Referring to FIG. 1, an electronic device ED of one or more embodiments may be a device that is to be activated in response to an electrical signal. For example, the electronic device ED may be a large device, such as a television, a monitor, and/or an external billboard. Furthermore, the electronic device ED may be a small-sized device or a medium-sized device, such as a personal computer, a laptop computer, a personal digital terminal, a car navigation unit, a game console, a smartphone, a tablet, and/or a camera. Furthermore, these are presented only as examples, and may be used as other electronic devices unless they deviate from the scope of the present disclosure.

The electronic device ED may be to display an image and/or a video through the display surface DD-IS. The display surface DD-IS may be parallel (e.g., substantially parallel) to a plane that is defined by a first direction DR1 and a second direction DR2. The display surface DD-IS may include a display area DA and a non-display area NDA.

A pixel PX may be arranged in the display area DA, and the pixel PX may not be arranged in the non-display area NDA. The non-display area NDA may be defined along a periphery of the display surface DD-IS. The non-display area NDA may be around (e.g., surround) the display area DA. However, embodiments of the present disclosure are not limited thereto, and the non-display area NDA may not be provided or the non-display area NDA may be arranged only on one side of the display area DA.

Although FIG. 1 illustrates an electronic device ED having a flat (e.g., substantially flat) display surface DD-IS, embodiments of the present disclosure are not limited thereto. The electronic device ED may include a curved display surface or a three-dimensional display surface. The three-dimensional display surface may include a plurality of display areas that indicate different directions.

A thickness direction of the electronic device ED may be a direction that is parallel (e.g., substantially parallel) to a third direction DR3 that is a thickness direction with respect to a plane defined by a first direction DR1 and a second direction DR2. The directions indicated by the first direction DR1, the second direction DR2, and the third direction DR3 as described in one or more embodiments are relative concepts, and may be converted to different directions.

In one or more embodiments, upper surfaces (or front surface) and lower surfaces (or rear surfaces) of the members that constitute the electronic device ED may be defined with respect to the third direction DR3. For example, among two surfaces that are opposite to (e.g., face) each other in one member in the third direction DR3, a surface that is relatively adjacent to the display surface DD-IS is defined as a front surface (or an upper surface), and a surface that is relatively spaced and/or apart (e.g., spaced apart or separated) from the display surface DD-IS may be defined as a rear surface (or a lower surface). Furthermore, in one or more embodiments, upper side and lower side may be defined with respect to the third direction DR3, the upper side may be defined as a direction that becomes closer to the display surface DD-IS, and the lower side may be defined as a direction that becomes more distant from the display surface DD-IS.

FIG. 2 is a cross-sectional view of an electronic device according to one or more embodiments of the present disclosure. FIG. 2 is a cross-sectional view of an electronic device according to one or more embodiments, which corresponds to the line I-I′ of FIG. 1.

Referring to FIG. 2, the electronic device ED may include a display panel DP and an optical structure layer PP that is arranged on the display panel DP. The display panel DP may include a display element layer DP-EL. The display element layer DP-EL may include a light emitting element EMD.

The optical structure layer PP may be arranged on the display panel DP to control reflected light on the display panel DP by external light. The optical structure layer PP may include, for example, a color filter layer CF, and may include a reflection prevention (or reduction) layer. A more detailed description of the optical structure layer PP will be described herein.

In the electronic device ED according to one or more embodiments, the display panel DP may be a light emitting display panel. For example, the display panel DP may be a light emitting diode (LED) display panel, an organic electroluminescence display panel, or a quantum dot light emitting display panel. However, embodiments of the present disclosure are not limited thereto. The display panel DP may provide a first light. For example, the display panel DP may be to emit a blue light as a source light.

The light emitting diode (LED) display panel may include a light emitting diode, a light emission layer of the organic electroluminescence display panel may include an organic electroluminescent material, and a light emission layer of the quantum dot light emitting display panel may include a quantum dot and/or a quantum rod. Hereinafter, the display panel DP included in the electronic device ED according to one or more embodiments of the present disclosure will be described as an organic electroluminescent display panel. However, embodiments of the present disclosure are not limited thereto.

The display panel DP may include a first base substrate BS, a circuit layer DP-CL, and a display element layer DP-EL.

The first base substrate BS may be a member that provides a base surface, on which the display element layer DP-EL is arranged. The first base substrate BS may be a glass substrate, a metal substrate, a plastic substrate, and/or the like. However, embodiments of the present disclosure are not limited thereto, and the first base substrate BS may be an inorganic layer, an organic layer, or a composite material layer. The first base substrate BS may be a flexible substrate that may be easily bent and/or folded.

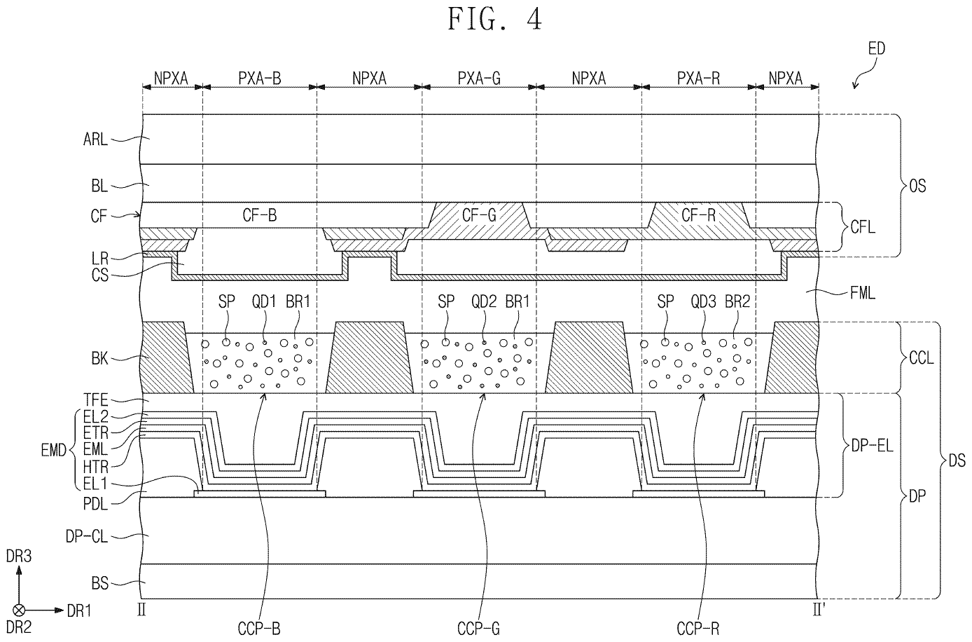

In one or more embodiments, the circuit layer DP-CL may be arranged on the first base substrate BS. The circuit layer DP-CL may include a plurality of transistors. Each of the transistors may include a control electrode, an input electrode, and an output electrode. For example, the circuit layer DP-CL may include a switching transistor and a driving transistor to drive a light emitting element EMD (FIG. 4) of the display element layer DP-EL.

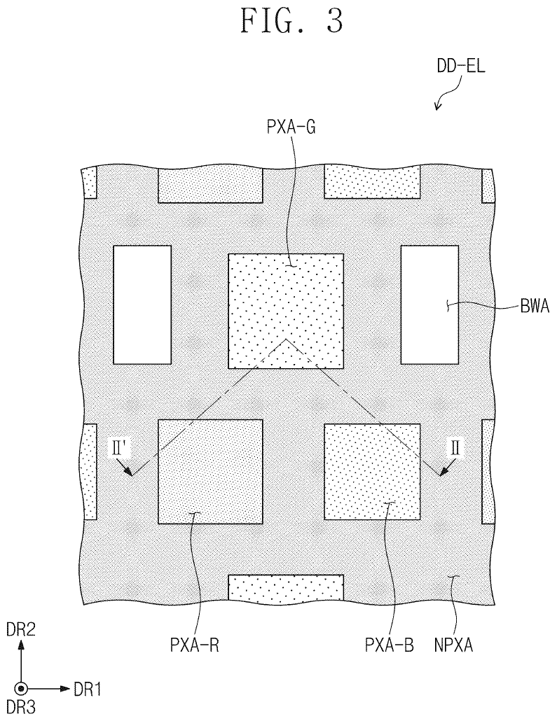

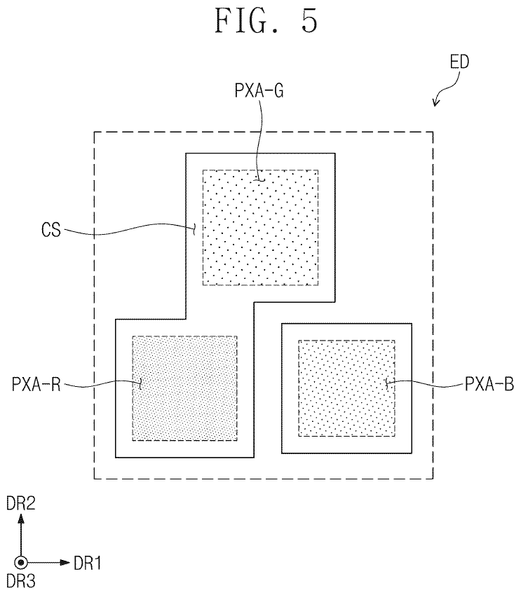

FIG. 3 is an enlarged plan view of a partial area of a display element layer DP-EL according to one or more embodiments of the present disclosure. FIG. 4 is a cross-sectional view of an electronic device according to one or more embodiments of the present disclosure. FIG. 5 is a plan view of a partial area of the electronic device illustrated in FIG. 4. FIG. 4 is a cross-sectional view that corresponds to the cutting line II-II′ illustrated in FIG. 3.

Referring to FIG. 3, the display element layer DP-EL may include three light emission areas PXA-B, PXA-G, and PXA-R. In one or more embodiments of the present disclosure, the three types (kinds) of light emission areas PXA-B, PXA-G, and PXA-R illustrated in FIG. 3 may be repeatedly arranged on the entire (e.g., substantially entire) display area DA (FIG. 1).

A non-emission area NPXA may be arranged around each of the first light emission area PXA-B, the second light emission area PXA-G, and the third light emission area PXA-R. The non-emission area NPXA may set a boundary between the first light emission area PXA-B, the second light emission area PXA-G, and the third light emission area PXA-R. The non-emission area NPXA may be around (e.g., surround) the first light emission area PXA-B, the second light emission area PXA-G, and the third light emission area PXA-R. In the non-emission area NPXA, a structure to prevent color mixing (or reduce a degree or occurrence of color mixing) between (or among) the first light emission area PXA-B, the second light emission area PXA-G, and the third light emission area PXA-R, for example, a pixel definition film PDL, may be arranged.

In FIG. 3, a first light emission area PXA-B, a second light emission area PXA-G, and a third light emission area PXA-R having substantially the same planar shape and different extents on a plane (e.g., in plan view) are illustrated by way of example, but embodiments of the present disclosure are not limited thereto. At least two extents of the first light emission area PXA-B, the second light emission area PXA-G, and the third light emission area PXA-R may be substantially the same. The extents of the first light emission area PXA-B, the second light emission area PXA-G, and the third light emission area PXA-R may be set depending on a light emission color. The extent of the light emission area that is to emit a green light, among primary colors, may be the largest, and the extent of the light emission area that is to emit a blue light may be the smallest. However, embodiments of the present disclosure are not limited to those illustrated in FIG. 3, and the extents of the first light emission area PXA-B, the second light emission area PXA-G, and the third light emission area PXA-R may be suitably changed. In one or more embodiments, the term “extent” may refer to an extent if (e.g., when) it is viewed on a plane (e.g., in plan view) defined by the first direction DR1 and the second direction DR2. For example, the light emission areas PXA-B, PXA-G, and PXA-R may have different extents depending on emitted colors. In one or more embodiments, the extent may refer to an extent if (e.g., when) it is viewed on a plane (e.g., in plan view) defined by the first direction DR1 and the second directions DR2. For example, the term “extent” may refer to the size or area of the light emission area when viewed on a plane (e.g., in plan view) defined by the first direction DR1 and the second direction DR2. For example, the light emission areas PXA-B, PXA-G, and PXA-R may have different extents depending on the emitted colors. In one or more embodiments, the extent refers to the size or area of the light emission area if (e.g., when) viewed on a plane (e.g., in plan view) defined by the first direction DR1 and the second direction DR2.

In FIG. 3, the first light emission area PXA-B, the second light emission area PXA-G, and the third light emission area PXA-R having a rectangular shape (e.g., a substantially rectangular shape) are illustrated, but embodiments of the present disclosure are not limited thereto. On a plane (e.g., in plan view), the first light emission area PXA-B, the second light emission area PXA-G, and the third light emission area PXA-R may have a polygonal shape (e.g., a substantially polygonal shape) having different shapes, such as a rhombus or a pentagon. In one or more embodiments, the first light emission area PXA-B, the second light emission area PXA-G, and the third light emission area PXA-R may have a rectangular shape (e.g., a substantially rectangular shape) having rounded corner areas on a plane (e.g., in plan view). An arrangement structure of the plurality of light emission areas is also not limited thereto. For example, in one or more embodiments, the light emission areas PXA-B, PXA-G, and PXA-R may have a PENTILE™ arrangement and/or a diamond PIXEL™ arrangement.

Referring to FIGS. 3 and 4, a bank well area BWA may be defined in the display area DA (FIG. 1). The bank well area BWA may be an area, in which a bank well is formed or arranged to prevent a defect (or reduce a degree or occurrence of a defect) due to a misattachment in a process of patterning a plurality of light control components (e.g., control parts or controllers) CCP-B, CCP-G, and CCP-R included in a light control layer CCL. For example, the bank well area BWA may be an area, in which a bank well formed or arranged by removing a portion of a partition part BK is defined.

In FIG. 3, two bank well areas BWA may be defined to be adjacent to the second light emission area PXA-G, by way of example, but the shape and arrangement of the bank well areas BWA may be suitably changed.

In the electronic device ED according to one or more embodiments as illustrated in FIGS. 3 and 4, three light emission areas PXA-B, PXA-G, and PXA-R that are to emit a blue light, a green light, and a red light are illustrated by way of example. For example, the electronic device ED according to one or more embodiments may include a blue light emission area PXA-B, a green light emission area PXA-G, and a red light emission area PXA-R, which are distinguished from each other.

In the electronic device ED as illustrated in FIG. 4, the light control layer CCL may be arranged while the upper surface of an encapsulation layer TFE is taken as a base surface, and the color filter layer CF may be arranged while the upper surface of the second base substrate BL (or a base member) is taken as a base surface. For example, the light control components CCP-B, CCP-G, and CCP-R of the light control layer CCL may be formed or arranged on the display panel DP through a substantially continuous process. The light control components CCP-B, CCP-G, and CCP-R may be formed or arranged while the upper surface of the encapsulation layer TFE is taken as the base surface, and the lower surface that is close to the encapsulation layer TFE may have an inverted tapered cross-sectional shape having a smaller width than that of the upper surface.

Referring to FIG. 4, the electronic device ED according to one or more embodiments may include a display substrate DS, an optical substrate OS, and a filling layer FML.

The display substrate DS may include a display panel DP and a light control layer CCL.

The display panel DP may include a first base substrate BS, a circuit layer DP-CL, and a display element layer DP-EL.

The display element layer DP-EL may include a pixel definition film PDL, a light emitting element EMD, and an encapsulation layer TFE.

Each of the light emission areas PXA-B, PXA-G, and PXA-R may be an area divided by the pixel definition film PDL. The non-emission area NPXA may be an area between adjacent light emission areas PXA-B, PXA-G, and PXA-R, and may be an area that corresponds to the pixel definition film PDL. In one or more embodiments, each of the light emission areas PXA-B, PXA-G, and PXA-R may correspond to a pixel. As illustrated in FIG. 4, an organic layer, such as a light emission layer EML included in the light emitting element EMD, may be provided as a common layer to overlap all of the light emission areas PXA-B, PXA-G, and PXA-R, and the non-emission area NPXA. In one or more embodiments, the light emission layer EML of the light emitting element EMD may be arranged and distinguished in an opening OH defined by the pixel definition film PDL.

The pixel definition film PDL may be formed of a polymer resin. For example, the pixel definition film PDL may be formed to include a polyacrylate-based resin and/or a polyimide-based resin. In one or more embodiments, the pixel definition film PDL may be formed to further include an inorganic material in addition to the polymer resin. In one or more embodiments, the pixel definition film PDL may be formed to include a light absorbing material or may be formed to include a black pigment and/or a black dye. The pixel definition film PDL formed to include the black pigment and/or the black dye may implement a black pixel definition film. If (e.g., when) the pixel definition film PDL is formed, carbon black and/or the like may be used as a black pigment and/or a black dye, but embodiments of the present disclosure are not limited thereto.

The pixel definition film PDL may be formed of an inorganic material. For example, the pixel definition film PDL may be formed to include silicon nitride (e.g., Si₃N₄ or SiNₓ, wherein 0<x≤2 ), silicon oxide (e.g., SiOₓ, wherein 0<x≤2; e.g., SiO₂), silicon oxynitride (e.g., Si₂N₂O or SiOₓN_{y}, wherein 0<x≤2 and 0≤y≤2; e.g., SiON), and/or the like. The pixel definition film PDL may define light emission areas PXA-B, PXA-G, and PXA-R. The light emission areas PXA-B, PXA-G, and PXA-R and the non-emission area NPXA may be distinguished by the pixel definition film PDL.

The light emitting element EMD may be arranged on the pixel definition film PDL. The light emitting element EMD may include a first electrode EL1, a second electrode EL2 that is opposite to (e.g., faces) the first electrode EL1, a light emission layer EML, and a plurality of functional layers that are arranged between the first electrode EL1 and the second electrode EL2.

A plurality of functional layers may include a hole transport area HTR and an electron transport area ETR. The hole transport area HTR may be arranged between the first electrode EL1 and the light emission layer EML. The electron transport area ETR may be arranged between the light emission layer EML and the second electrode EL2. In one or more embodiments, an element capping layer may be further arranged on the second electrode EL2.

Each of the hole transport area HTR and the electron transport area ETR may include a plurality of sub-functional layers. For example, the hole transport area HTR may include a hole injection layer and a hole transport layer as the sub-functional layers, and the electron transport area ETR may include an electron injection layer and an electron transport layer as the sub-functional layers. However, embodiments of the present disclosure are not limited thereto, and the hole transport area HTR may further include an electron blocking layer and/or the like as a sub-functional layer, and the electron transport area ETR may further include a hole blocking layer and/or the like as a sub-functional layer.

The first electrode EL1 may have conductivity (e.g., electrical conductivity).

The first electrode EL1 may be formed of a metal alloy and/or a conductive (e.g., electrically conductive) compound. The first electrode EL1 may be an anode. The first electrode EL1 may be a pixel electrode. The first electrode EL1 may be a reflective electrode. However, embodiments of the present disclosure are not limited thereto, and the first electrode EL1 may be a transmissive electrode, a transflective electrode, and/or the like. If (e.g., when) the first electrode EL1 is a transflective electrode or a reflective electrode, the first electrode EL1 may have a plurality of layer structures including silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca, LiF/Al, molybdenum (Mo), titanium (Ti), or a (e.g., any suitable) compound and/or a (e.g., any suitable) mixture thereof (for example, a mixture of Ag and Mg). In one or more embodiments, the structure may be a plurality of layers including a reflective film formed of the exemplified materials herein, a transflective film, and a transparent (e.g., substantially transparent) conductive (e.g., electrically conductive) film formed of indium tin oxide (ITO), indium zinc oxide (IZO), zinc oxide (ZnO), indium tin zinc oxide (ITZO), and/or the like. For example, the first electrode EL1 may be a multi-layered metal layer, and may be a structure, in which metal layers of ITO/Ag/ITO are laminated.

The hole transport area HTR may be provided on the first electrode EL1. The hole transport area HTR may include a hole injection layer, a hole transport layer, and/or the like. The hole transport area HTR may have a single layer formed of a single material, a single layer formed of a plurality of different materials, or a multi-layered structure having a plurality of layers formed of a plurality of different materials.

The hole transport area HTR may be formed by using one or more suitable methods, such as vacuum deposition, spin coating, casting, a Langmuir-Blodgett (LB) method, inkjet printing, laser printing, and/or laser-induced thermal imaging (LITI).

The hole transport area HTR may include, for example, carbazole-based derivatives, such as N-phenylcarbazole and/or polyvinylcarbazole, fluorene-based derivatives, triphenylamine-based derivatives, such as N,N′-bis(3-methylphenyl)-N, N′-diphenyl-(1,1-biphenyl)-4,4′-diamine (TPD), 4,4′,4″ tris(carbazol-9-yl)triphenylamine (TCTA), N,N′-di(naphthalene-1-yl)-N,N′-diphenyl-benzidine (NDP), 4,4′-bis[N, N-bis(4-methylphenyl)benzenamine] (TAPC), 4,4′-bis[N,N′-(3-tolyl)amino]-3,3'-dimethylbiphenyl (HMTPD), 1,3-bis(N-carbazolyl)benzene (mCP), and/or the like.

A thickness of the hole transport area HTR may range from about 5 nm to about 1,500 nm, for example, from about 10 nm to about 500 nm. If (e.g., when) the thickness of the hole transport area HTR satisfies the foregoing ranges, a satisfactory or suitable degree of hole transport characteristics may be obtained without substantially increasing the driving voltage.

The light emission layer EML may be provided on the hole transport area HTR. The light emission layer EML may include a host and a dopant. In one or more embodiments, the light emission layer EML may include an organic light emitting material as a dopant material. In one or more embodiments, the light emission layer EML may include quantum dots as a dopant material. In one or more embodiments, the light emission layer EML may further include an organic host material in addition to the dopant material. In the display panel DP of one or more embodiments, the light emission layer EML included in the light emitting element EMD may be to emit a blue light having a center wavelength of 420 nm or more and 480 nm or less.

In the light emitting element EMD of one or more embodiments, the electron transport area ETR may be provided on a light emission layer EML. The electron transport area ETR may include at least one selected from among an electron transport layer and an electron injection layer, but embodiments of the present disclosure are not limited thereto.

The electron transport area ETR may have a single layer formed of a single material, a single layer formed of a plurality of different materials, or a multi-layered structure having a plurality of layers formed of a plurality of different materials. For example, the electron transport area ETR may have a single-layered structure of an electron injection layer or an electron transport layer and may have a single-layered structure including an electron injection material and an electron transport material.

The thickness of the electron transport area ETR may be, for example, about 20 nm to about 150 nm.

The electron transport area ETR may be formed by using one or more suitable methods, such as vacuum deposition, spin coating, casting, a Langmuir-Blodgett (LB) method, inkjet printing, laser printing, and/or laser-induced thermal imaging (LITI).

The electron transport area ETR may include, for example, an anthracene-based compound, tris(8-hydroxyquinolinato)aluminum (Alq₃), 1,3,5-tri[(3-pyridyl)-phen-3-yl]benzene, 2,4,6-tris(3'-(pyridin-3-yl)biphenyl-3-yl)-1,3,5-triazine, bis[2-(diphenylphosphino)phenyl] ether oxide (DPEPO), 2-(4-(N-phenylbenzoidazolyl-1-ylphenyl)-9,10-dinaphthylanthracene, 1,3-tri(1-phenyl-1H-benzo[d]imidazol-2-yl)phenyl (TPBi), and/or a (e.g., any suitable) mixture thereof. In one or more embodiments, the electron transport area ETR may include a halogenated metal, such as LiF, NaCl, CsF, RbCl, and/or RbI, a lanthanide metal, such as Yb, a metal oxide, such as Li₂O and/or BaO, and/or lithium quinolate (Liq).

The second electrode EL2 may be provided on the electron transport area ETR. The second electrode EL2 may be a common electrode or a negative electrode. The second electrode EL2 may be a transmissive electrode, a transflective electrode, or a reflective electrode. If (e.g., when) the second electrode EL2 is a transmissive electrode, the second electrode EL2 may be formed of a transparent (e.g., substantially transparent) metal oxide, for example, indium tin oxide (ITO), indium zinc oxide (IZO), zinc oxide (ZO), indium tin zinc oxide (ITZO), and/or the like. If (e.g., when) the second electrode EL2 is a transflective electrode or a reflective electrode, the second electrode CE may be formed of Ag, Mg, Cu, Al, Pt, Pd, Au, Ni, Nd, Ir, Cr, Li, Ca, LiF/Ca, LiF/Al, Mo, Ti, Yb or a (e.g., any suitable) compound or a (e.g., any suitable) mixture including the element as described in one or more embodiments. In one or more embodiments, the structure may be a multi-layered structure including a reflective film formed of the materials as described in one or more embodiments, a transflective film, and a transparent (e.g., substantially transparent) conductive (e.g., electrically conductive) film formed of indium tin oxide (ITO), indium zinc oxide (IZO), zinc oxide (ZnO), indium tin zinc oxide (ITZO), and/or the like.

The second electrode EL2 may be connected to an auxiliary electrode. If (e.g., when) the second electrode EL2 is connected to the auxiliary electrode, a resistance (e.g., electrical resistance) of the second electrode EL2 may be decreased.

The encapsulation layer TFE may be arranged on the light emitting element EMD to cover the light emitting element EMD. The encapsulation layer TFE may be one layer or a plurality of layers that are laminated. The encapsulation layer TFE may be a thin film encapsulation layer. The encapsulation layer TFE may be arranged to protect the light emitting element EMD. The encapsulation layer TFE may cover an upper surface of the second electrode EL2 arranged on the opening OH and may fill the opening OH.

The optical substrate OS may be arranged on the display substrate DS. The optical substrate OS may include a reflection prevention layer ARL, a second base substrate BL, a color filter layer CF, column patterns CS, and a low-refraction layer LR.

The light control layer CCL may include a plurality of partition parts BK that are arranged to be spaced and/or apart (e.g., spaced apart or separated) from each other and light control components CCP-B, CCP-G, and CCP-R that are arranged between the partition parts BK. The light control layer CCL may be arranged on the display panel DP. Upper surfaces of the light control components CCP-B, CCP-G, and CCP-R and an upper surfaces of the partition parts BK may be stepped from each other. However, embodiments of the present disclosure are not limited thereto, and the upper surfaces of the light control components CCP-B, CCP-G, and CCP-R and the upper surfaces of the partition parts BK may be aligned.

The light control layer CCL may include a photoconductor. The photoconductor may be a quantum dot and/or a phosphor. The photoconductor may be to convert the provided light into a wavelength and emit it. For example, the light control layer CCL may be a layer including quantum dots in at least a portion thereof or a layer including phosphors.

The light control layer CCL may be formed on the filling layer FML.

Accordingly, the partition part BK may have a cross-sectional shape, in which an upper surface that is adjacent to the filling layer FML has a width that is smaller than that of the lower surface.

The partition part BK may be formed including a polymer resin and/or a liquid-repellent additive. The partition part BK may be formed to include a light-absorbing material or may be formed including a pigment and/or a dye. The partition part BK may be formed to include a black pigment and/or a black dye to implement a black partition part. If (e.g., when) the black partition part is formed, carbon black may be used as a black pigment and/or a black dye, but embodiments of the present disclosure are not limited thereto.

The light control layer CCL may include a first light control component CCP-B that is to transmit a first light that is the source light provided from the light emitting element EMD, a second light control component CCP-G that is to convert the first light into a second light, and a third light control component CCP-R that is to convert the first light into a third light. The second light may be a light in a longer wavelength area than the first light, and the third light may be light in a longer wavelength area than the first light and the second light. For example, the first light may be a light having an emission wavelength of about 410 nm or more and about 480 nm or less, the second light may be a light having an emission wavelength of about 500 nm or more and about 600 nm or less, and the third light may be a light having an emission wavelength of about 620 nm or more and about 700 nm or less. The first light may be a blue light, the second light may be a green light, and the third light may be a red light.

A light emitter may be included in each of the second light control component CCP-G and the third light control component CCP-R. A light emitter may be a particle that is to emit light having a different wavelength after converting a wavelength of input light. In one or more embodiments, the light emitter included in the second light control component CCP-G and the third light control component CCP-R may be a quantum dot and/or a phosphor. The second light control component CCP-G may include a first quantum dot QD1 that is to convert the first light into the second light, and the third light control component CCP-R may include a second quantum dot QD2 that is to convert the first light into the third light. The first light control component CCP-B may be a transmissive part that is to transmit the first light without converting the wavelength of the first light and may not include (e.g., may exclude) a (e.g., any) separate light emitter. However, embodiments of the present disclosure are not limited thereto, and a light emitter, such as a quantum dot, which is to convert the light input to the first light control component CCP-B into the first light may be included.

Quantum dots may be selected from among Group II-VI compounds, Group I-II-VI compounds, Group II-IV-VI compounds, Group I-II-IV-VI compounds, Group I-III-VI compounds, Group III-V compounds, Group III-IV-V compounds, Group II-IV-V compounds, Group IV-VI compounds, Group IV elements, Group IV compounds, and/or one or more (e.g., any suitable) combinations thereof.

The Group II-VI compound may be selected from the group consisting of a diatomic compound selected from the group consisting of CdSe, CdTe, CdS, ZnS, ZnSe, ZnTe, ZnO, HgS, HgSe, HgTe, MgSe, MgS, and one or more (e.g., any suitable) mixtures thereof, a triatomic compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more (e.g., any suitable) mixtures thereof, a four-element compound selected from the group consisting of HgZnTeS, CdZnSeS, CdZnSeTe, CdZnSTe, CdHgSeS, CdHgSeTe, CdHgSTe, HgZnSeS, HgZnSeTe, and one or more (e.g., any suitable) mixtures thereof. In one or more embodiments, the Group II-VI compound may further include a Group I metal and/or a Group IV element. The Group I-II-VI compound may be selected from among CuSnS or CuZnS, and the Group II-IV-VI compound may be selected from among ZnS and/or the like. The Group I-II-IV-VI compound may be selected from the group consisting of Cu₂ZnSnS₂, Cu₂ZnSnS₄, Cu₂ZnSnSe₄, Ag₂ZnSnS₂, and one or more (e.g., any suitable) mixtures thereof.

The Group III-VI compound may include a diatomic compound, such as In₂S₃ and/or In₂Se₃, a triatomic compound, such as InGaS₃ and/or InGaSe₃, or a (e.g., any suitable) combination thereof.

The Group I-III-VI compound may be selected from the group consisting of a triatomic compound selected from the group consisting of AgInS, AgInS₂, CuInS, CuInS₂, AgGaS₂, CuGaO₂, AgGaO₂, AgAlO₂, and one or more (e.g., any suitable) mixtures thereof, or a four-element compound, such as AgInGaS₂, CuInGaS₂, and/or CuInGaS₂.

The Group III-V compound may be selected from the group consisting of a diatomic compound selected from the group consisting of GaN, GaP, GaAs, GaSb, AlN, AlP, AlAs, AlSb, InN, InP, InAs, InSb, and one or more (e.g., any suitable) mixtures thereof, a triatomic component selected from the group consisting of GaNP, GaNAs, GaNSb, GaPAs, GaPSb, AlNAs, AlNSb, AlPAs, AlPSb, InGaP, InAlP, InNP, InNAs, InNSb, InPAs, InPSb, InPSb, and one or more (e.g., any suitable) mixtures thereof, and a four-element compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more (e.g., any suitable) mixtures thereof. In one or more embodiments, the Group III-V compound may further include a Group II metal. For example, InZnP and/or the like may be selected as the Group III-II-V compound.

The Group II-IV-V compound may be a triatomic compound selected from the group consisting of ZnSnP, ZnSnP₂, ZnSnAs₂, ZnGeP₂, CdSnP₂, and CdGeP₂, and one or more (e.g., any suitable) mixtures thereof.

The Group IV-VI compound may be selected from the group consisting of a diatomic component selected from the group consisting of SnS, SnSe, SnTe, PbS, PbSe, PbTe, and one or more (e.g., any suitable) mixtures thereof; a triatomic component selected from the group consisting of SnSeS, SnSeTe, SnSTe, PbSeS, PbSeTe, PbSTe, SnPbS, SnPbSe, SnPbTe, and one or more (e.g., any suitable) mixtures thereof; and a four-element compound selected from the group consisting of SnPbSSe, SnPbSeTe, SnPbSTe, and one or more (e.g., any suitable) mixtures thereof. The Group IV element may be selected from the group consisting of Si, Ge, and one or more (e.g., any suitable) mixtures thereof. The Group IV compound may be a diatomic compound selected from the group consisting of SiC, SiGe, and one or more (e.g., any suitable) mixtures thereof.

In one or more embodiments, the diatomic compound, the triatomic compound, or the four-element compound may be present in the particle at a substantially uniform concentration or may be present in substantially the same particle in a state, in which the concentration distribution is divided to be partially different. Furthermore, one quantum dot may have a core/shell structure that is around (e.g., surrounds) another quantum dot. In the core/shell structure, the concentration of the element that is present in the shell may have a concentration gradient, in which it decreases as it goes toward the core.

In one or more embodiments, the quantum dot may have a core-shell structure that includes a core including the nanocrystal as described in one or more embodiments and a shell that is around (e.g., surrounds) the core. The shell of the quantum dot may act or serve as a protective layer to maintain semiconductor properties by preventing chemical denaturation (or reducing a degree or occurrence of chemical denaturation) of the core and/or a charging layer to impart or provide electrophoretic properties to the quantum dots. The shell may have a single layer or multiple layers. Examples of the shell may include an oxide of a metal and/or a non-metal, a semiconductor compound, and/or a (e.g., any suitable) combination thereof.

The shell may include a material that is different from that of the core. For example, the core may include a first semiconductor nanocrystal, and the shell may include a second semiconductor nanocrystal that is different from the first semiconductor nanocrystal. In one or more embodiments, the shell may include an oxide of a metal and/or a non-metal. The shell may include an oxide of a metal and/or a non-metal, semiconductor nanocrystals, and/or a (e.g., any suitable) combination thereof.

The shell may be formed of a single material, but may also be formed to have a concentration gradient. For example, the shell may have a concentration gradient, in which the concentration of the second semiconductor nanocrystals that are present in the shell decreases and the concentration of the first semiconductor nanocrystals that are contained in the core increases as it becomes closer to the core. In one or more embodiments, the shell may have a multi-layered structure including different materials.

For example, an example of the metal oxide and/or the non-metal oxide may be a diatomic compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, CoO, Co₃O₄, and/or NiO, or a triatomic compound, such as MgAl₂O₄, CoFe₂O₄, NiFe₂O₄, and/or CoMn₂O₄, but embodiments of the present disclosure are not limited thereto.

Furthermore, an example of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

Quantum dots may have a full width of half maximum (FWHM) of an emission wavelength spectrum of about 45 nm or less, for example, about 40 nm or less, and, for example, about 30 nm or less, and in the foregoing ranges, a color purity and/or a color reproducibility may be improved or enhanced. Furthermore, because the light emitted through the quantum dots is emitted in all directions, the viewing angle of the light may be improved or enhanced.

Furthermore, the shape of quantum dots is not limited to those generally used in the art, but, for example, spherical (e.g., substantially spherical), pyramid-shaped (e.g., substantially pyramid-shaped), multi-arm (e.g., substantially multi-arm), and/or cubic (e.g., substantially cubic) nanoparticles, nanotubes, nanowires, nanofibers, and/or nanofibers may be used.

Quantum dots may adjust the color of the emitted light depending on the size of the particles, and accordingly, the quantum dots may have one or more suitable emission colors, such as blue, red, and green. As the size of the particles of the quantum dot becomes smaller, light in the shorter wavelength area may be emitted. For example, the size of the particles of the quantum dots having substantially the same core, which emit a green light, may be smaller than the size of the particles of the quantum dots that emit a red light. Furthermore, the size of the particles of the quantum dots having substantially the same core, which emit a blue light, may be smaller than the size of the particles of the quantum dots that emit a green light. However, embodiments of the present disclosure are not limited thereto, and the size of the particles may be adjusted depending on a shell forming material and a shell thickness even in the quantum dots having substantially the same core.

In contrast, if (e.g., when) the quantum dots have one or more suitable emission colors, such as blue, red, and/or green, the quantum dots having different emission colors may have different core materials.

Quantum dots may adjust the color of the emitted light depending on the size of the particles, and accordingly, the quantum dots may have one or more suitable emission colors, such as blue, red, and green. As the size of the particles of the quantum dot becomes smaller, light in the shorter wavelength area may be emitted. For example, the size of the particles of the quantum dots that emit a green light may be smaller than the size of the particles of the quantum dots that emit a red light, and the size of the particles of the quantum dots that emit a blue light may be smaller than the size of the particles of the quantum dots that emit a green light.

Each of a plurality of light control components CCP-B, CCP-G, and CCP-R included in the light control layer CCL may further include a scatterer (e.g., a light scatterer) SP. The first light control component CCP-B may include only the scatterer SP, the second light control component CCP-G may include the first quantum dot QD1 and the scatterer SP, and the third light control component CCP-R may include the second quantum dot QD2 and the scatterer SP.

The scattering body SP may be inorganic particles. For example, the scatterer SP may include at least one selected from among TiO₂, ZnO, Al₂O₃, SiO₂, and hollow silica. The scatterer SP may include any one selected from among TiO₂, ZnO, Al₂O₃, SiO₂, and hollow silica or may include a mixture of two or more materials selected from among TiO₂, ZnO, Al₂O₃, SiO₂, and hollow silica.

Each of the first light control component CCP-B, the second light control component CCP-G, and the third light control component CCP-R may include base resins BR1, BR2, and BR3 that disperse the quantum dots QD1 and QD2 and the scatterer SP. In one or more embodiments, the first light control component CCP-B may include a scatterer SP dispersed in the first base resin BR1, and the second light control component CCP-G may include the first quantum dot QD1 and the scatterer SP dispersed in the second base resin BR2, and the third light control component CCP-R may include the second quantum dot QD2 and the scatterer SP dispersed in the third base resin BR3. The base resins BR1, BR2, and BR3 that are media, in which the quantum dots QD1 and QD2 and the scatterer SP are dispersed, may be formed of one or more suitable resin compositions that may be generally referred to as binders. For example, the base resins BR1, BR2, and BR3 may be acrylic resins, urethane resins, silicone resins, epoxy resins, and/or the like. The base resins BR1, BR2, and BR3 may be transparent (e.g., substantially transparent) resins. In one or more embodiments, the first base resin BR1, the second base resin BR2, and the third base resin BR3 may be substantially the same or different.

The color filter layer CF may include color filters. The color filter layer CF may include a first color filter CF-B that is to transmit a portion of a source light, a second color filter CF-G that is to transmit the first light, and a third color filter CF-R that is to transmit the second light. In one or more embodiments, the color filter layer CF may include a first color filter CF-B that is to transmit a blue light, a second color filter CF-G that is to transmit a green light, and a third color filter CF-R that is to transmit a red light. In one or more embodiments, the first color filter CF-B may be a blue filter, the second color filter CF-G may be a green filter, and the third color filter CF-R may be a red filter.

Each of the color filters CF may include a polymer photosensitive resin and a colorant. The first color filter CF-B may include a blue colorant, the second color filter CF-G may include a green colorant, and the third color filter CF-R may include a red colorant. The first color filter CF-B may include a blue pigment and/or a blue dye, the second color filter CF-G may include a green pigment and/or a green dye, and the third color filter CF-R may include a red pigment and/or a red dye.

Each of the first color filter CF-B, the second color filter CF-G, and the third color filter CF-R may be arranged in correspondence to each of the first light emission area PXA-B, the second light emission area PXA-G, and the third light emission area PXA-R. Furthermore, each of the first color filter CF-B, the second color filter CF-G, and the third color filter CF-R may be arranged in correspondence to each of the first light control component CCP-B, the second light control component CCP-G, and the third light control component CCP-R.

Furthermore, the plurality of color filters CF-B, CF-G, and CF-R that are to transmit different lights may be arranged to overlap each other in correspondence to the non-emission areas NPXA arranged between the light emission areas PXA-B, PXA-G, and PXA-R. The plurality of color filters CF-B, CF-G, and CF-R may be arranged to overlap each other in the third direction DR3, which is the thickness direction, to distinguish boundaries between adjacent light emission areas PXA-B, PXA-G, and PXA-R. Accordingly, the light shielding effect for external light may be increased or enhanced to have substantially the same function as that of a black matrix. The overlapping structure of the plurality of color filters CF-B, CF-G, and CF-R may have a function of preventing color mixing (or reducing a degree or occurrence of color mixing).

In one or more embodiments, the color filter layer CF may include a light shielding part to distinguish the boundaries between the adjacent color filters CF-B, CF-G, and CF-R. The light shielding part may be formed of a blue filter or may be formed of a black pigment and/or an organic light shielding material and/or an inorganic light shielding material including a black pigment.

Embodiments of the present disclosure are not limited thereto, and the first color filter CF-B may not include (e.g., may exclude) a (e.g., any) pigment and/or a (e.g., any) dye. The first color filter CF-B may include a polymer photosensitive resin and may not include (e.g., may exclude) a (e.g., any) pigment and/or a (e.g., any) dye. The first color filter CF-B may be transparent (e.g., substantially transparent). The first color filter CF-B may be formed of a transparent (e.g., substantially transparent) photosensitive resin.

The color filter layer CF may further include a buffer layer BFL. For example, the buffer layer BFL may be a protective layer that is to protect the filters CF-B, CF-G, and CF-R. The buffer layer BFL may be an inorganic material layer including at least one inorganic material that is selected from among silicon nitride, silicon oxide, and silicon oxynitride. The buffer layer BFL may be formed of a single layer or a plurality of layers.

In one or more embodiments, as illustrated in FIG. 4, the first color filter CF-B of the color filter layer CF may overlap the second color filter CF-G and the third color filter CF-R, but embodiments of the present disclosure are not limited thereto. For example, the first color filter CF-B, the second color filter CF-G, and the third color filter CF-R may be distinguished by the light shielding parts and may not overlap each other. In one or more embodiments, each of the first color filter CF-B, the second color filter CF-G, and the third color filter CF-R may be arranged in correspondence to a blue light emission area PXA-B (or a first light emission area), a green light emission area PXA-G (or a second light emission area), and a red light emission area PXA-R (or a third light emission area).

Referring to FIGS. 4 and 5, a plurality of column patterns CS may be provided. The column patterns CS may be arranged between the color filters CF-B, CF-G, and CF-R and the low-refraction layer LR. The column patterns CS may overlap the light emission areas PXA-B, PXA-G, and PXA-R, respectively. On a plane (e.g., in plan view), an extent of each of the column patterns may be greater than an extent of each of the light emission areas PXA-B, PXA-G, and PXA-R. At least a portion of each of the column patterns CSs may overlap the pixel definition film PDL on a plane (e.g., in plan view). However, embodiments of the present disclosure are not limited thereto, and the extent of each of the column patterns CS may be substantially the same as the extent of each of the light emission areas PXA-B, PXA-G, and PXA-R on a plane (e.g., in plan view). If (e.g., when) the extent of each of the column patterns CS is equal to or greater than the extent of each of the light emission areas PXA-B, PXA-G, and PXA-R, a substantially uniform color may be implemented by preventing or reducing color mixing between adjacent light emission areas PXA-B, PXA-G, and PXA-R.

Furthermore, a damage to the light emitting element EMD may be reduced or prevented by mitigating external impacts.

One selected from among the plurality of column patterns CS may overlap at least two selected from among the plurality of light emission areas PXA-B, PXA-G, and PXA-R. For example, one column pattern CS may overlap the second light emission area PXA-G and the third light emission area PXA-R at the same time (e.g., concurrently). However, embodiments of the present disclosure are not limited thereto, and one column pattern CS may overlap the first light emission area PXA-B and the second light emission area PXA-G or the first light emission area PXA-B and the third light emission area PXA-R at the same time (e.g., concurrently).

The column patterns CS may be formed of a transparent (e.g., substantially transparent) organic material. Thicknesses of the column patterns CS may be about 0.1 μm or more. The thickness of the column patterns CS may be smaller than a thickness of the filling layer FML.

The column patterns CS may have a transmittance of about 95% or more in an area having a wavelength of about 380 nm to about 780 nm. If (e.g., when) the column patterns CS have a transmittance of a specific (e.g., set or predetermined) level or more, a degree of light efficiency that is reduced by additionally disposing the column patterns CS in the light emission areas PXA-B, PXA-G, and PXA-R may be minimized or reduced.

The low-refraction layer LR may be arranged under the column patterns CS. The low-refraction layer LR may be arranged between the light control layer CCL and the color filters CF-B, CF-G, and CF-R. The low-refraction layer LR may have an integral shape (e.g., a substantially integral shape). The low-refraction layer LR may be arranged on the light control layer CCL to prevent the light control components CCP1, CCP2, CCP3, and CCP4 from being exposed to moisture/oxygen (or reduce a degree to or occurrence of which the light control components CCP1, CCP2, CCP3, and CCP4 are exposed to moisture/oxygen). Furthermore, the low-refraction layer LR may be arranged between the light control components CCP1, CCP2, CCP3, and CCP4 and the color filters CF-B, CF-G, and CF-R to increase or enhance light extraction efficiency or function as an optical functional layer, for example, to prevent the reflected light from being input to the light control layer CCL (or reduce a degree to or occurrence of which the reflected light is input to the light control layer CCL). The low-refraction layer LR may be a layer having a smaller reflective index compared to an adjacent layer. For example, a refractive index of the low-refraction layer LR may be lower than a refractive index of the column patterns CS and a refractive index of the filling layer FML. For example, the refractive index of the low-refraction layer LR may be about 1.05 or more and about 1.4 or less, and the refractive index of the column patterns CS may be about 1.2 or more and about 2.0 or less. If (e.g., when) the low-refraction layer LR has a refractive index that is lower than that of the filling layer FML, the upper surface of the filling layer FML may be easily totally reflected. If (e.g., when) the refractive index of the low-refraction layer LR is about 1.4 or less, it may be advantageous or beneficial to reduce a total reflection threshold angle of the upper surface of the filling layer FML. This may increase an amount of light that is totally reflected and improve or enhance a usage efficiency of light.

The low-refraction layer LR may include at least one inorganic layer. For example, the low-refraction layer LR may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film having a light transmittance. However, embodiments of the present disclosure are not limited thereto, and the low-refraction layer LR may include an organic film. For example, it may be formed to include a low-refraction layer LR that is formed from a polymer resin and inorganic particles. The low-refraction layer LR may include a single layer or a plurality of layers.

The filling layer FML may be arranged between the display substrate DS and the optical substrate OS. In one or more embodiments, the filling layer FML may be filled between the light control layer CCL and the color filter layer CF. The filling layer FML may be arranged directly on the first barrier layer CAP1, and the color filter layer CF may be arranged directly on the filling layer FML. A lower surface of the filling layer FML may contact an upper surface of the first barrier layer CAP1, and an upper surface of the filling layer FML may contact lower surfaces of the color filters CF1, CF2, and CF3 of the color filter layer CF.

The filling layer FML may be to function as an impact absorber between the light control layer CCL and the color filter layer CF. In one or more embodiments, the filling layer FML may be to perform an impact absorbing function and/or the like and may be to increase or enhance a strength of the display panel DP. The filling layer FML may be formed from a filling resin including a polymer resin. For example, the filling layer FML may be formed from a filling layer resin including an acrylic resin and/or an epoxy resin.

In one or more embodiments, the filling layer FML may be arranged between the light control layer CCL and the color filter layer CF to increase or enhance a light extraction efficiency or may be to function as an optical functional layer, for example, to prevent reflected light from being input to the light control layer CCL (or reduce a degree to or occurrence of which reflected light is input to the light control layer CCL). The filling layer FML may be a layer having a lower reflective index compared to an adjacent layer.

An optical layer OPL of the electronic device ED according to one or more embodiments may further include a polarizing layer. The polarizing layer may be to shield the external light provided to the display panel DP from the outside. The polarizing layer may be to shield a portion of the external light. If (e.g., when) the electronic device ED includes a polarizing layer, the color filter layer CF may not be provided.

Furthermore, the polarizing layer may be to reduce the reflected light (e.g., a degree or occurrence of the reflected light) generated from the display panel DP by the external light. For example, the polarizing layer may be to shield the reflected light if (e.g., when) the light provided from the outside of the electronic device ED is input to the display panel DP and is output again. The polarizing layer may be a circular polarizer (e.g., a substantially circular polarizer) having a reflection preventing or reducing function, or the polarizing layer may include a linear polarizer and a λ/4 phase delayer.

In one or more embodiments, the electronic device ED according to one or more embodiments may further include an overcoat layer OC. The overcoat layer OC may be arranged on the color filter layer CF. The overcoat layer OC may include an organic layer. The overcoat layer OC may include an organic material having a high strength and high planarization characteristics. The overcoat layer OC may provide a flat (e.g., substantially flat) upper surface. In one or more embodiments, the overcoat layer OC may perform a function of an upper base layer that provides a reference surface on the color filter layer CF. The overcoat layer OC may be a member that provides a base surface, on which the optical layer OPL and the light control layer CCL are arranged. The overcoat layer OC may be an inorganic layer, an organic layer, or a (e.g., any suitable) composite material layer. However, embodiments of the present disclosure are not limited thereto, and the overcoat layer OC may be a glass substrate, a metal substrate, a plastic substrate, and/or the like.

The reflection prevention layer ARL may be arranged on the color filter layer CF. The reflection prevention layer ARL may contact the upper surface of the color filter layer CF. The reflection prevention layer ARL may be a layer having a low reflectivity to shield the blocking external light. The reflection prevention layer ARL may be a layer having a plurality of layers having different refractive indexes to effectively or suitably shield the external light through offset interferences. A reflectance on the upper surface of the reflection prevention layer ARL may be about 2% or less. In a range of visible light of about 430 nm to about 780 nm, a reflectance on the upper surface of the reflection prevention layer ARL may be about 2% or less. At a wavelength of about 550 nm, the reflectance on the upper surface of the reflection prevention layer ARL may be about 2% or less.

According to one or more embodiments, if (e.g., when) the column patterns CS are arranged in the light emission areas PXA-B, PXA-G, and PXA-R, respectively, a distance between the low-refraction layer LR and the light control layer CCL may become smaller compared to a case, in which the column patterns CS are not arranged in the light emission areas PXA-B, PXA-G, and PXA-R. As the distance between the low-refraction layer LR and the light control layer CCL becomes smaller, the total reflection may further occur in the optical layer OPL due to a deviation of the refractive indexes of the low-refraction layer LR and the adjacent layers CS and FML. Accordingly, an amount of the recycled light, among the lights emitted through the quantum dots QD1 and QD2, may be increased. Accordingly, the light efficiency of the electronic device ED may be improved or enhanced.

If (e.g., when) the column patterns CS are arranged in the light emission areas PXA-B, PXA-G, and PXA-R, respectively, an extent ratio occupied by the column patterns CS on a plane (e.g., in plan view) may be increased compared to a case, in which the column patterns CS are arranged only on the partition part BK. Accordingly, a margin of formation of the column patterns CS may be increased in the high-resolution display panel, in which the extent of the partition part BK becomes relatively smaller.

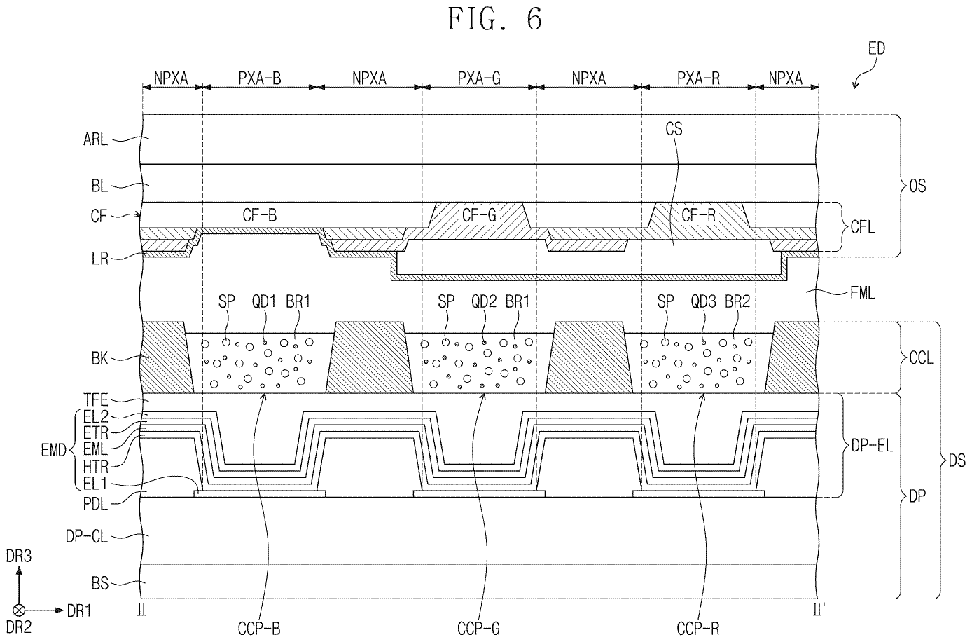

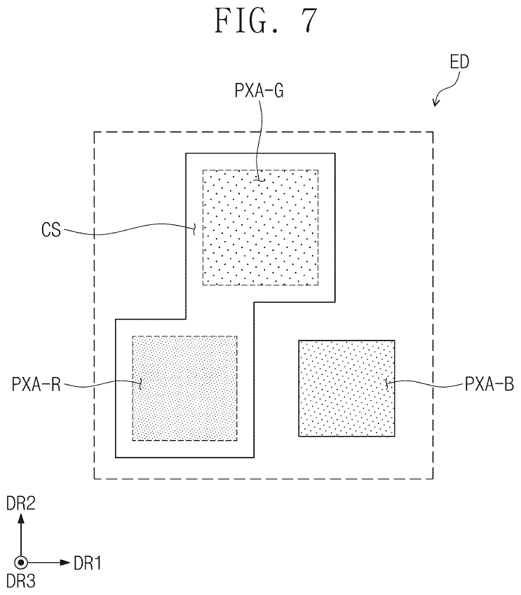

FIG. 6 is a cross-sectional view of an electronic device according to one or more embodiments of the present disclosure. FIG. 7 is a plan view of a partial area of the electronic device as illustrated in FIG. 6. Hereinafter, in the description with reference to FIGS. 6 and 7, the same/similar reference numerals are used for substantially the same/similar configurations or arrangements as described in FIGS. 3 to 5, and a repeated description thereof may not be provided.

Referring to FIGS. 6 and 7, the column patterns CS may not overlap the first light emission area PXA-B. The column patterns CS may not be arranged in the first light emission area PXA-B. For example, the column patterns CS may be arranged only in the second light emission area PXA-G and the third light emission area PXA-R. Unlike the second light emission area PXA-G and the third light emission area PXA-R, the first light emission area PXA-B may be to emit the transmitted light and may not form new light through the quantum dots QD1 and QD2, and thus, an amount of the recycled light may not be affected even if (e.g., when) the column patterns CS are arranged in the first light emission area PXA-B. Because the column patterns CS are not arranged in the first light emission area PXA-B, a possibility of reducing the front efficiency of transmitted light may be lowered.

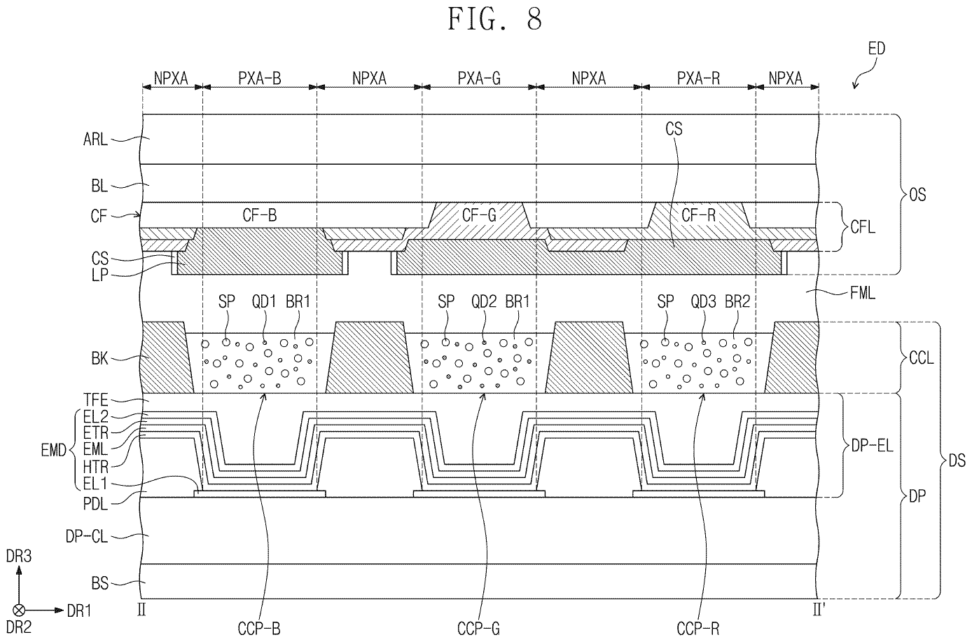

FIG. 8 is a cross-sectional view of an electronic device according to one or more embodiments of the present disclosure. Hereinafter, in the description with reference to FIG. 8, the same/similar reference numerals are used for substantially the same/similar configurations or arrangements as described in FIGS. 3 to 5, and a repeated description thereof may not be provided.

Referring to FIG. 8, the column patterns CS may overlap the non-light emission area NPXA and may not overlap the light emission areas PXA-B, PXA-G, and PXA-R.

The low-refraction layer LR may include a plurality of low-refraction patterns LP that are spaced and/or apart (e.g., spaced apart or separated) from each other. The low-refraction patterns LP may be arranged between two adjacent column patterns CS of the column patterns CS. A refractive index of the low-refraction patterns LP may be lower than a refractive index of the column patterns CS. The refractive index of the low-refraction patterns LP may be lower than a refractive index of the filling layer FML. If (e.g., when) the refractive index of the low-refraction patterns LP is lower than the refractive index of the filling layer FML, a light extraction efficiency may be improved or enhanced. The refractive index of the low-refraction patterns LP may be about 1.05 or more and about 1.4 or less, and the refractive index of the column patterns CS may be about 1.2 or more and about 2.0 or less. If (e.g., when) the low-refraction patterns LP have a refractive index that is lower than that of the filling layer FML, the upper surface of the filling layer FML may be easily totally reflected. If (e.g., when) the refractive index of the low-refraction patterns LP is about 1.4 or less, it may be advantageous or beneficial to reduce a total reflection threshold angle of the upper surface of the filling layer FML. This may increase an amount of light that is totally reflected and improve or enhance a usage efficiency of light.

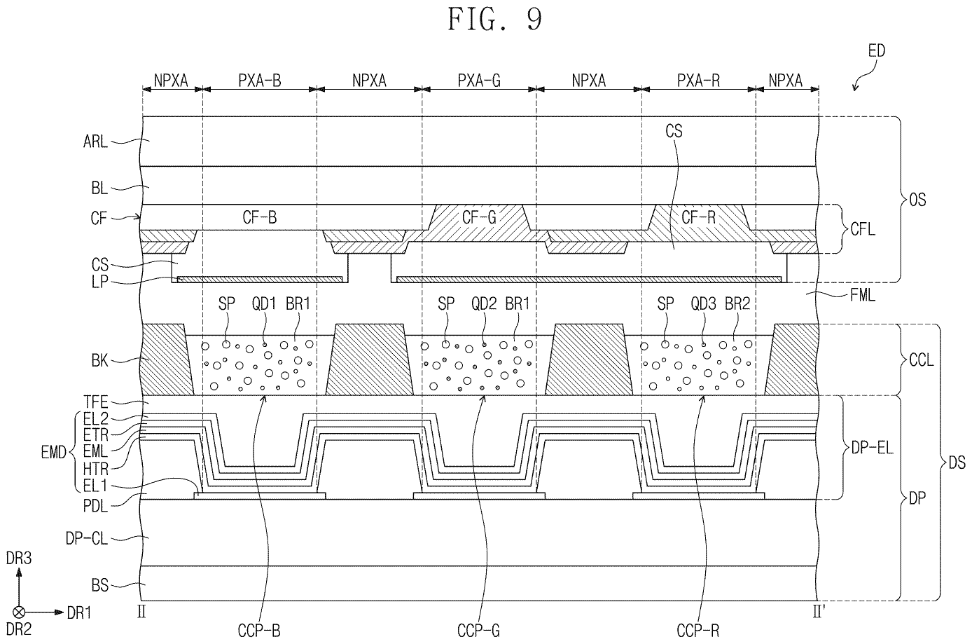

FIG. 9 is a cross-sectional view of an electronic device according to one or more embodiments of the present disclosure. Hereinafter, in the description with reference to FIG. 9, the same/similar reference numerals are used for substantially the same/similar configurations or arrangements as described in FIGS. 3 to 5, and a repeated description thereof may not be provided.

Referring to FIG. 9, a recessed part RP may be defined on a lower surface of each of the column patterns CS. At least a portion of the recessed part RP may overlap the pixel definition film PDL on a plane (e.g., in plan view).

The low-refraction layer LR may include a plurality of low-refraction patterns LP that are spaced and/or apart (e.g., spaced apart or separated) from each other. The low-refraction patterns LP may be arranged on the recessed parts RP, respectively. A thickness of the low-refraction patterns LP may be about 2 μm or less.

One selected from among the plurality of low-refraction patterns LP may overlap at least two selected from among the plurality of light emission areas PXA-B, PXA-G, and PXA-R. For example, one low-refraction pattern LP may overlap the second light emission area PXA-G and the third light emission area PXA-R at the same time (e.g., concurrently). However, embodiments of the present disclosure are not limited thereto, and one low-refraction pattern LP may overlap the first light emission area PXA-B and the second light emission area PXA-G or the first light emission area PXA-B and the third light emission area PXA-R at the same time (e.g., concurrently).

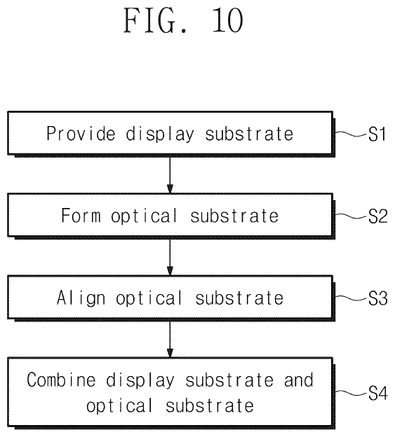

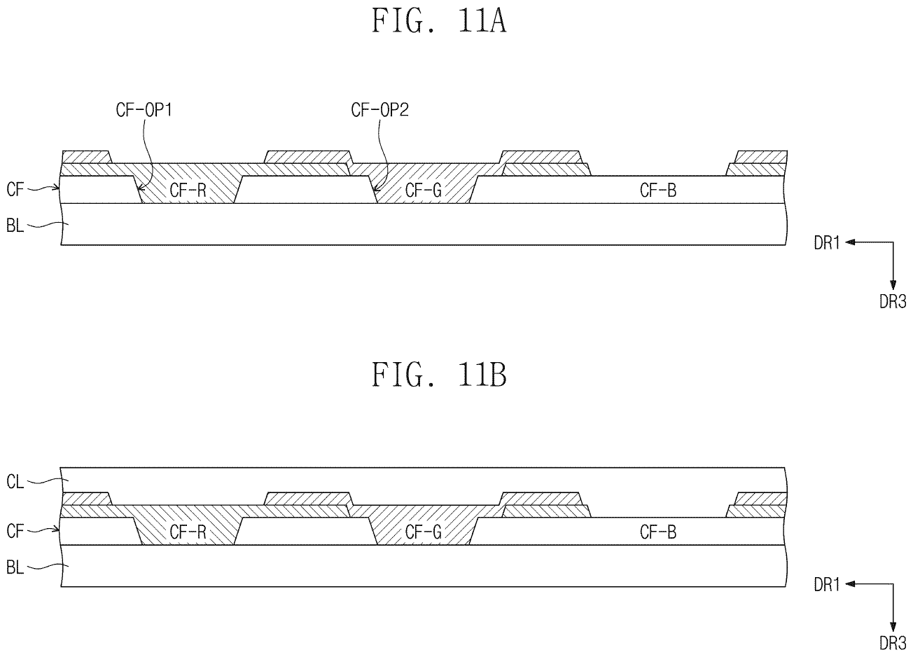

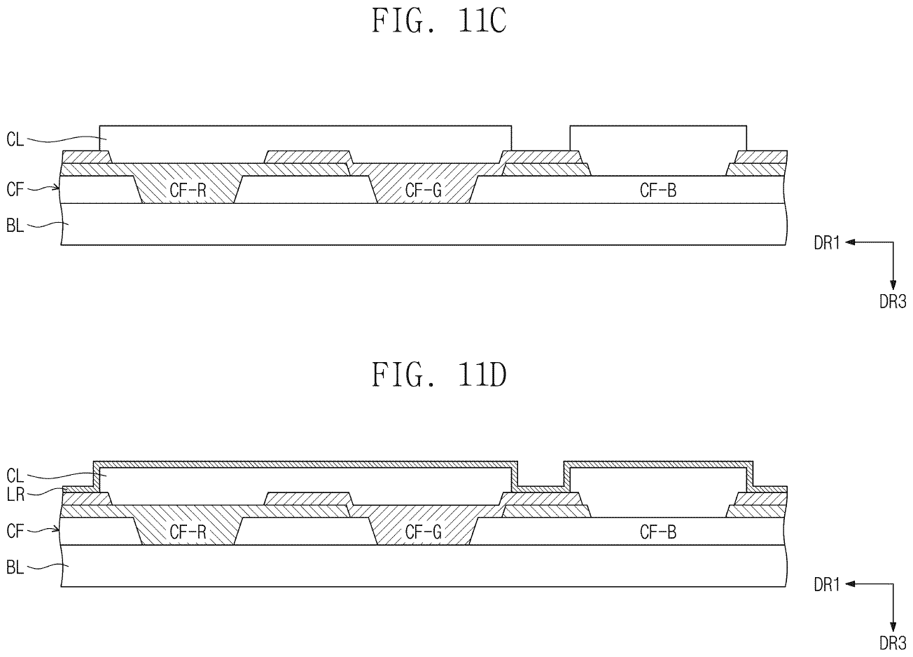

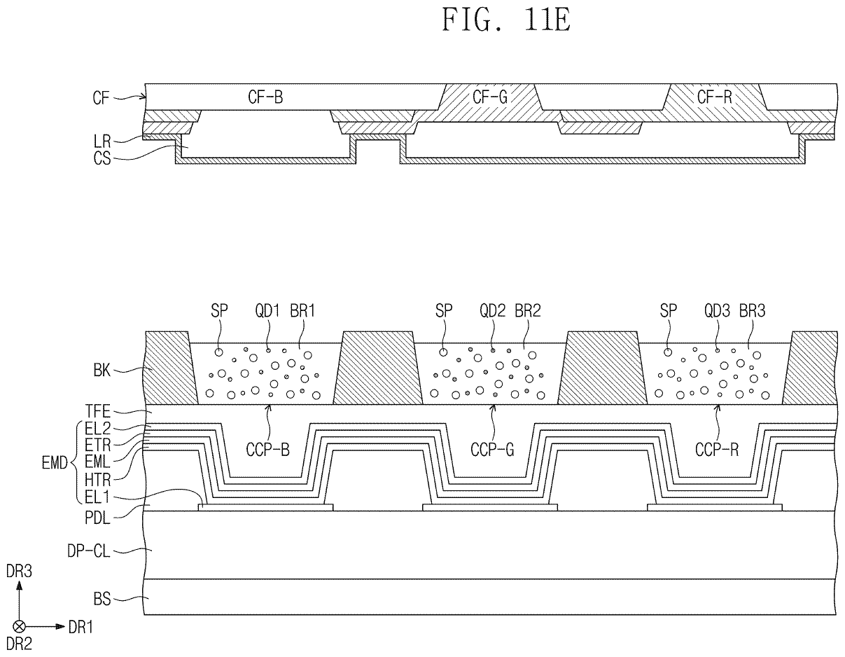

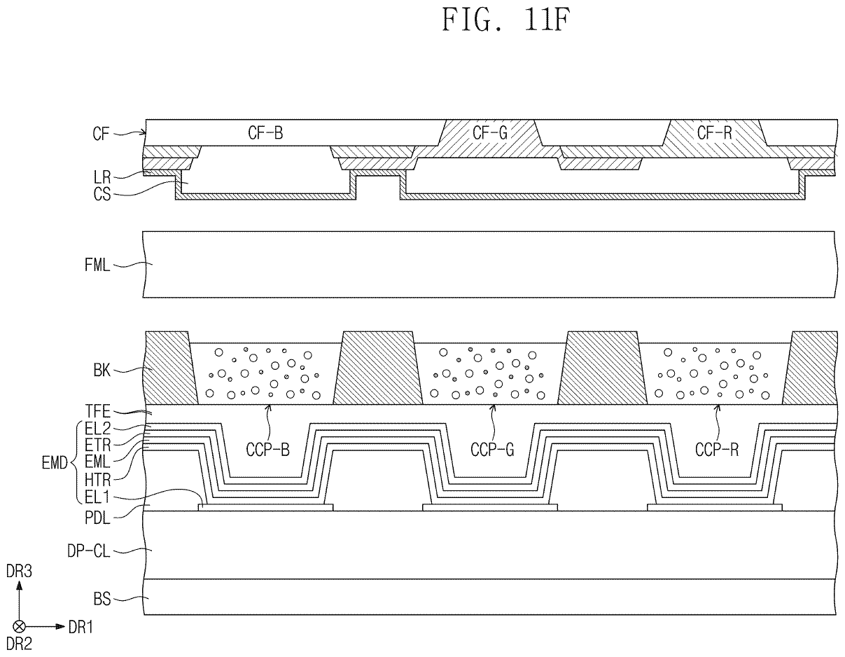

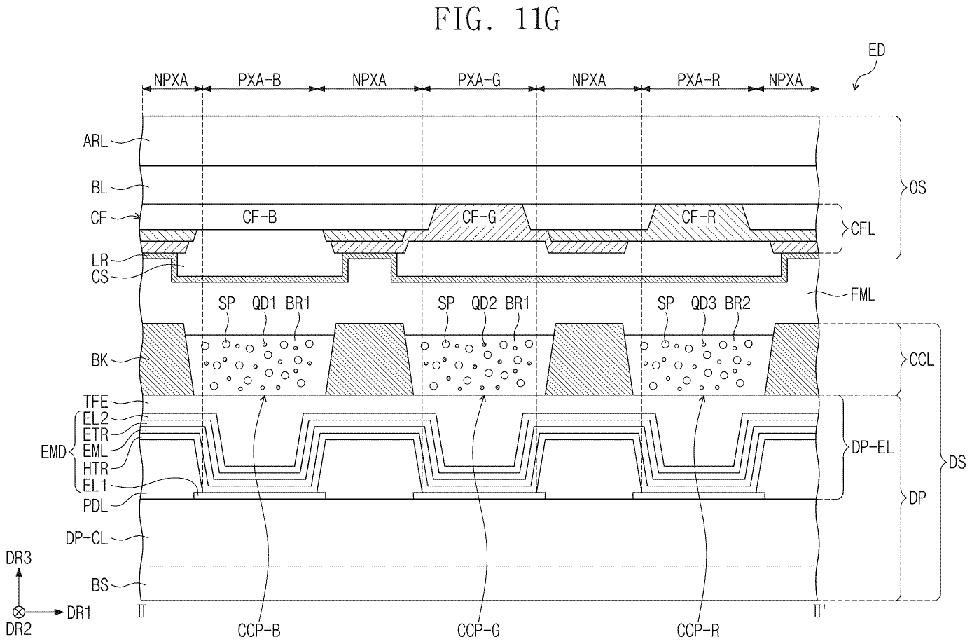

FIG. 10 is a block diagram illustrating a manufacturing sequence of an electronic device according to one or more embodiments of the present disclosure. FIGS. 11A to 11G are cross-sectional views illustrating one or more operations of a method for manufacturing an electronic device according to one or more embodiments of the present disclosure. FIGS. 11A to 11G illustrate cross-sectional views of a manufacturing method of one or more embodiments as illustrated in FIG. 4.

Hereinafter, in the description with reference to FIGS. 10 to 13D, the same/similar reference numerals are used for substantially the same/similar configurations or arrangements as described in FIGS. 3 to 5, and a repeated description thereof may not be provided.

Referring to FIG. 10, a method for manufacturing an electronic device according to one or more embodiments of the present disclosure may include an operation S1 of providing a display substrate, an operation S2 of forming an optical substrate, an operation S3 of aligning the optical substrate, and an operation S4 of combining the display substrate and the optical substrate.

FIGS. 11A to 11G may correspond to the operation S2 of forming an optical substrate.

Referring to FIG. 11A, a color filter layer CF may be formed or arranged on a base member BL. The color filter layer CF may be formed or arranged by forming or arranging a plurality of openings CF-OP1 and CF-OP2 on an initial layer and disposing or arranging color patterns that correspond to the openings CF-OP1 and CF-OP2, respectively. The first opening CF-OP1 and the second opening CF-OP2 may be formed or arranged on the first color filter CF-B according to one or more embodiments. The first color filter CF-B may be formed or arranged by depositing and/or coating a layer, in which a colorant is mixed with a photosensitive resin, on the base member BL and then removing portions that correspond to the first opening CF-OP1 and the second opening CF-OP2.

Thereafter, a third color filter CF-R may be formed or arranged in the first opening CF-OP1, and then a second color filter CF-G may be formed or arranged in the second opening CF-OP2. In one or more embodiments, portions of the second color filter CF-G and the third color filter CF-R may overlap on the partition part BK, and a portion of the second color filter CF-G may be formed or arranged on a portion of the third color filter CF-R. A portion, at which the second color filter CF-G and the third color filter CF-R are laminated, may have relatively higher light shielding properties than the partition part BK, and thus may act or serve as a function that corresponds to a black matrix. However, this is illustrated by way of example, and a lamination sequence of the second color filter CF-G and the third color filter CF-R may be different from each other, and a portion, at which the second color filter CF-G and the third color filter CF-R are laminated, may not be provided, and is not limited to any one or more embodiments.

Referring to FIG. 11B, a column layer CL may be formed or arranged on a color filter layer CF. The column layer CL may be formed or arranged by depositing and/or coating a transparent (e.g., substantially transparent) organic material on the color filter layer CF. The column layer CL may be formed or arranged to cover an entire (e.g., substantially entire) extent of an upper surface of the color filter layer CF.

Referring to FIG. 11C, a plurality of column patterns CS may be formed by patterning the column layer CL thereafter. The column patterns CS may be formed by selectively patterning the column layer CL through a photolithography and an etching process. One selected from among a plurality of column patterns CS may be formed to overlap both (e.g., simultaneously) the second color filter CF-G and the third color filter CF-R if (e.g., when) viewed on a plane (e.g., in plan view), and the other thereof may be formed to overlap the first color filter CF-B. In one or more embodiments, the column patterns CS may be formed of a transparent (e.g., substantially transparent) organic material. The column patterns CS may be formed to have a thickness of about 0.1 μm or more.

Referring to FIG. 11D, a low-refraction layer LR may be formed or arranged on the column patterns CS. The low-refraction layer LR may be formed or arranged by coating an organic material and/or an inorganic material on the column patterns CS. The low-refraction layer LR may be formed or arranged to cover the entire (e.g., substantially entire) surfaces of the column patterns CS.

Referring to FIG. 11E, an optical substrate OS may be provided on a display substrate DS. In one or more embodiments, the optical substrate OS and the display substrate DS may be aligned. As described in one or more embodiments, the display substrate DS may include a display panel DP and a light control layer CCL, and the display panel DP may include a first base substrate BS, a circuit layer DP-CL, and a display element layer DP-EL.

The color filters CF-B, CF-G, and CF-R of the optical substrate OS may be aligned to overlap the light control components CCP-B, CCP-G, and CCP-R of the display substrate DS on a plane (e.g., in plan view), respectively. In one or more embodiments, the optical substrate OS may be arranged such that the low-refraction layer LR is opposite to (e.g., faces) the display substrate DS.

Referring to FIGS. 11F and 11G, the optical substrate OS and the display substrate DS may be combined with each other with a filling layer FML therebetween. The filling layer FML may be formed of an epoxy resin and/or an acrylic resin. The optical substrate OS and the display substrate DS may be pressed to be combined with each other. In one or more embodiments, the filling layer FML may be cured by heat and/or ultraviolet rays.

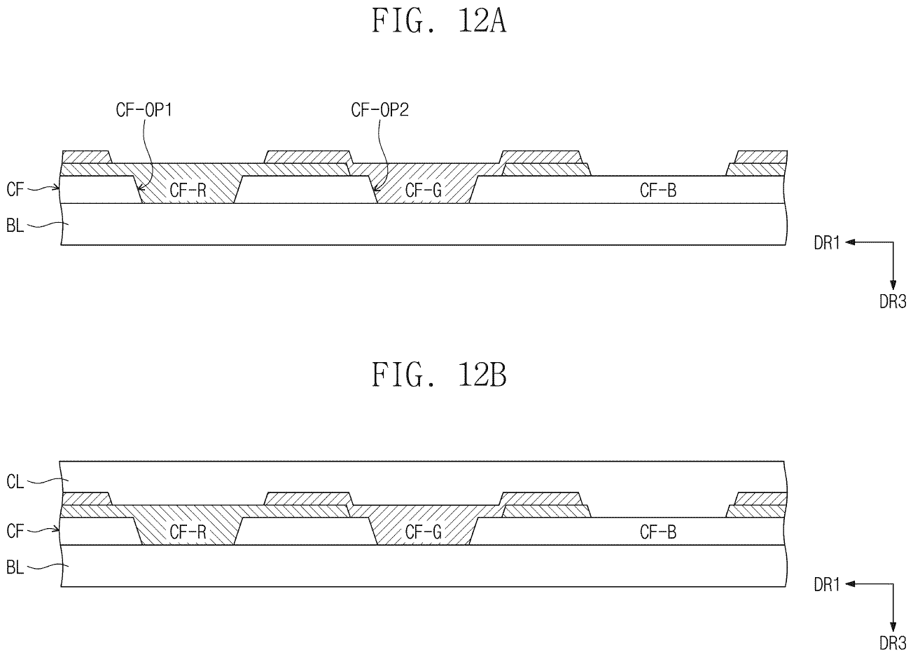

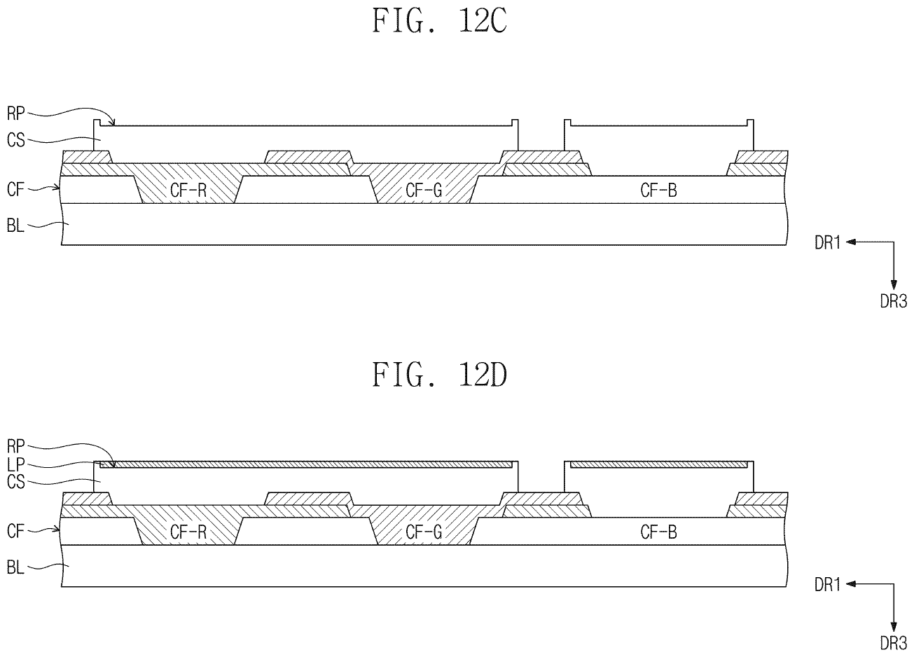

FIGS. 12A to 12D are cross-sectional views illustrating a method for manufacturing the optical substrate OS according to one or more embodiments of the present disclosure. Operations that correspond to FIGS. 11A to 11G are illustrated in FIGS. 12A to 12D, respectively. Hereinafter, the present disclosure will be described in more detail with reference to FIGS. 12A to 12D. In one or more embodiments, a configuration or arrangement that is substantially the same as the configuration or arrangement as described with reference to FIGS. 1 to 11G is marked by the same reference numerals/symbols, and thus, additional description may not be provided to avoid redundancy.

Referring to FIGS. 12A and 12B, a column layer CL may be formed or arranged on the color filter layer CF.

Hereinafter, referring to FIG. 12C, the operation S2 of forming the optical substrate OS according to one or more embodiments of the present disclosure may further include an operation of forming a recessed part RP on the column patterns CP. The recessed parts RP may be formed by using a half-tone mask. The recessed part RP formed on the upper surfaces of the column patterns CS may be formed to have a hydrophobic surface. As the recessed part RP is formed to have a low step difference of about 2 μm or less, the amount and costs of the materials used to form the low-refraction layer LR may be reduced.

Referring to FIG. 12D, the low-refraction patterns LP may be formed on the column patterns CS. The low-refraction patterns LP may be formed in the recessed parts RP, respectively. The low-refraction patterns LP may be formed through an inkjet printing method. The low-refraction patterns LP may be formed by providing an ink composition in the recessed parts RP, respectively. Although FIG. 12D illustrates that the low-refraction patterns LP have substantially the same thickness, embodiments of the present disclosure are not limited thereto, and the low-refraction patterns LP may be formed to have different thicknesses.

Referring to FIGS. 12C and 12D, in one or more embodiments of the present disclosure, one selected from among a plurality of column patterns CS may be formed to overlap at least two selected from among a plurality of color filters CF-B, CF-G, and CF-R. One selected from among the recessed parts RP formed on the upper surfaces of the column patterns CS may be formed to overlap at least two selected from among a plurality of color filters CF-B, CF-G, and CF-R.

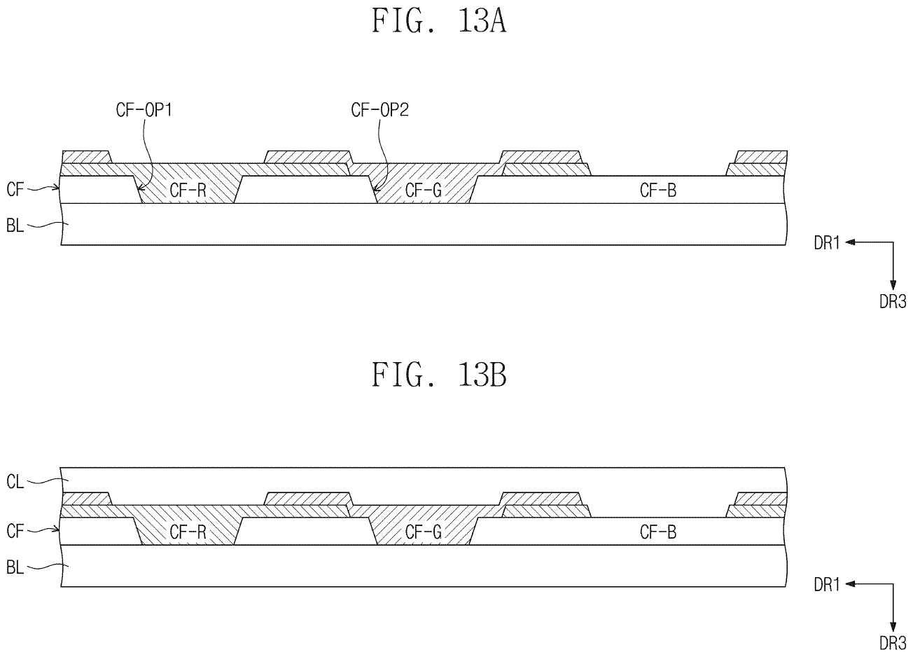

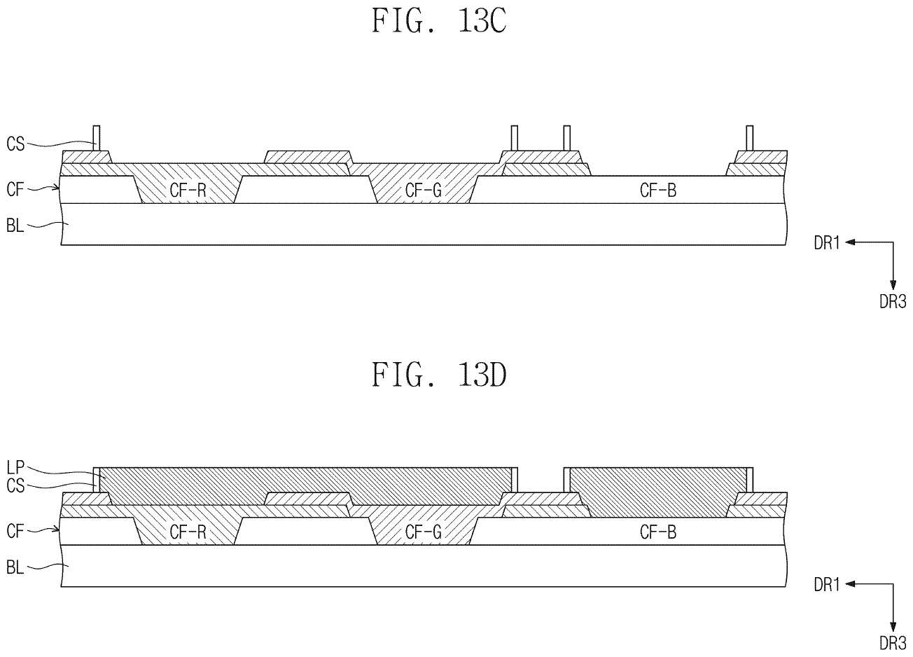

FIGS. 13A to 13D are cross-sectional views illustrating a method for manufacturing a first substrate according to one or more embodiments of the present disclosure. In FIGS. 13A to 13D, operations that correspond to FIGS. 11A to 11G are illustrated, respectively. Hereinafter, the present disclosure will be described in more detail with reference to FIGS. 13A to 13D. In one or more embodiments, a configuration or arrangement that is substantially the same as the configuration or arrangement as described with reference to FIGS. 1 to 12D is marked by the same reference numerals/symbols, and thus, additional description may not be provided to avoid redundancy.

Referring to FIGS. 13A and 13B, a column layer CL may be formed or arranged on the color filter layer CF.

Referring to FIG. 13C, a plurality of column patterns CS may be formed by patterning the column layer CL. The column patterns CS may be formed by selectively patterning the column layer CL through a photolithography and an etching process.

The column patterns CS may be formed to overlap the non-light emission area NPXA and not to overlap the light emission areas PXA-B, PXA-G, and PXA-R. In one or more embodiments, the column patterns CS may be formed of a transparent (e.g., substantially transparent) organic material.

Referring to FIG. 13D, the low-refraction patterns LP may be formed on the column patterns CS. The low-refraction layer LR may include a plurality of low-refraction patterns LP that are spaced and/or apart (e.g., spaced apart or separated) from each other. The low-refraction patterns LP may be formed through an inkjet printing method. The low-refraction patterns LP may be formed on the color filters CF-B, CF-G, and CF-R. The low-refraction patterns LP may be formed by providing an ink composition between two adjacent column patterns CS, among the column patterns CS. In one or more embodiments, the ink composition may be provided to have an upper surface aligned with an upper surface of the column patterns CS. If (e.g., when) one column pattern CS is formed to overlap two or more light emission areas that are to emit light of different colors, the number of column patterns CS formed may be reduced compared to the case, in which one column pattern CS is formed to overlap light emission areas PXA-B, PXA-G, and PXA-R that are to emit lights of different colors. Accordingly, a process accuracy may be improved or enhanced in the process of forming low-refraction patterns LP by applying an ink composition on the column patterns CS.

According to one or more embodiments, the optical characteristics of the electronic device may be improved or enhanced by reducing the distance between the light control component and the low refraction layer to increase or enhance an excitation efficiency. For example, the integration of the low-refraction patterns within the recessed parts of the column patterns may further enhance the light management within the device. By precisely controlling the placement and thickness of these low-refraction patterns, it may be feasible to achieve a more uniform light distribution and minimize or reduce optical losses. This may lead to improved brightness and color accuracy in the emitted light, thereby enhancing the overall performance of the electronic device.

The light-emitting element, the display apparatus/device, the electronic apparatus/device, the manufacturing apparatuses thereof, or any other relevant apparatuses/devices or components according to one or more embodiments of the present disclosure described herein may be implemented utilizing any suitable hardware, firmware (e.g., an application-specific integrated circuit), software, or a combination of software, firmware, and hardware. For example, the one or more suitable components of the device may be formed on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of one or more embodiments of the present disclosure.

In the present disclosure, each suitable feature of the one or more embodiments of the disclosure may be combined or combined with one another, partially or entirely, and may be technically interlocked and operated in one or more suitable ways, and each embodiment may be implemented independently of one another or in conjunction with one another in any suitable manner unless otherwise stated or implied.

Although one or more embodiments of the present disclosure have been described with reference to the accompanying drawings, those of ordinary skill in the art to which the present disclosure pertains will understand that the subject matter of the present disclosure may be embodied in different forms and should not be construed as being limited to one or more embodiments set forth herein. It therefore will be understood that one or more embodiments described herein are just illustrative but not limitative in all aspects.

What is claimed is:

1. An electronic device, comprising:
a first base substrate;
a second base substrate on the first base substrate;
a filling layer between the first base substrate and the second base substrate;
a pixel definition film between the first base substrate and the filling layer and defining a first light emission area, a second light emission area, and a third light emission area, the first to third light emission areas being to emit different lights, the pixel definition film further defining a non-light emission area adjacent to the first to third light emission areas;
a plurality of light emitting elements in the first to third light emission areas, respectively;
a light control layer arranged on the non-light emission area and comprising partition walls, in which openings that correspond to the first to third light emission areas are defined, and a plurality of light control components arranged in the openings, respectively, and each of the plurality of light control components comprises a quantum dot;
a plurality of column patterns overlapping the first to third light emission areas, respectively; and
a low-refraction layer between the plurality of column patterns and the light control layer,
wherein one selected from among the plurality of column patterns overlaps the first light emission area and the second light emission area.

2. The electronic device as claimed in claim 1, wherein, in plan view, an area of each of the plurality of column patterns is greater than an area of each of the first to third light emission areas, and
at least a portion of each of the plurality of column patterns overlaps the pixel definition film, on the plane.

3. The electronic device as claimed in claim 1, wherein the low-refraction layer has an integral shape.

4. The electronic device as claimed in claim 1, wherein thicknesses of the plurality of column patterns are smaller than a thickness of the filling layer.

5. The electronic device as claimed in claim 1, wherein recessed parts are defined on lower surfaces of the plurality of column patterns, respectively, and
wherein the low-refraction layer comprises a plurality of low-refraction patterns spaced from each other and is arranged in the recessed parts, respectively.

6. The electronic device as claimed in claim 5, wherein, in plan view, an area of each of the recessed parts is greater than an area of each of the first to third light emission areas, and
wherein at least a portion of each of the recessed parts overlaps the pixel definition film, on the plane.

7. The electronic device as claimed in claim 5, wherein thicknesses of the plurality of low-refraction patterns are about 2 μm or less.

8. The electronic device as claimed in claim 1, wherein a refractive index of the low-refraction layer is smaller than refractive indexes of the plurality of column patterns.

9. The electronic device as claimed in claim 1, further comprising:
a color filter layer arranged on the plurality of column patterns and comprising a color filter.

10. The electronic device as claimed in claim 1, wherein the plurality of light emitting elements comprise the first light emission area to emit a blue light, the second light emission area to emit a green light, and the third light emission area to emit a red light, and
wherein the plurality of column patterns do not overlap the first light emission area in plan view.

11. An electronic device, comprising:
a display substrate;
an optical substrate on the display substrate; and
a filling layer between the display substrate and the optical substrate,
wherein the display substrate comprises:
a pixel definition film defining a plurality of light emission areas and non-light emission areas adjacent to the plurality of light emission areas;
a plurality of light emitting elements in the plurality of light emission areas, respectively;
partition walls arranged on the non-light emission areas and comprising openings corresponding to the plurality of light emission areas; and
a plurality of light control components arranged in the partition walls, respectively, and comprising a quantum dot,
wherein the optical substrate comprises:
a plurality of column patterns overlapping the non-light emission areas; and
a plurality of low-refraction patterns arranged between two adjacent ones selected from among the plurality of column patterns and spaced from each other, and
wherein at least portions of the plurality of low-refraction patterns overlap the plurality of light emission areas in plan view.

12. The electronic device as claimed in claim 11, wherein thicknesses of the plurality of low-refraction patterns are smaller than a thickness of the filling layer.

13. The electronic device as claimed in claim 11, wherein refractive indexes of the plurality of low-refraction patterns are smaller than refractive indexes of the plurality of column patterns.

14. A method, comprising:
providing a base member;
forming a column layer on the base member;
forming a plurality of column patterns spaced from each other, by patterning the column layer;
forming a low-refraction layer on the plurality of column patterns;
providing a display substrate comprising a first light emission element, a second light emission element, and a third light emission element, the first to third light emission elements being to emit different lights;
arranging the display substrate such that the low-refraction layer and the first to third light emission elements are opposite to each other; and
forming a filling layer between the low-refraction layer and the display substrate,
wherein one selected from among the plurality of column patterns overlaps the first light emission element and the second light emission element, and
wherein the method is a method for manufacturing an electronic device.

15. The method as claimed in claim 14, wherein entire surfaces of the plurality of column patterns are coated to form the low-refraction layer.

16. The method as claimed in claim 14, wherein recessed parts are arranged on upper surfaces of the plurality of column patterns by utilizing a half-tone mask.

17. The method as claimed in claim 16, wherein depths of the recessed parts are about 2 μm or less.

18. The method as claimed in claim 16, wherein the low-refraction layer comprises a plurality of low-refraction patterns spaced from each other, and
wherein the plurality of low-refraction patterns are arranged in the recessed parts, respectively.

19. The method as claimed in claim 18, wherein the plurality of low-refraction patterns are arranged through an ink-jet printing process.

20. The method as claimed in claim 14, further comprising:
combining the low-refraction layer and the display substrate to each other.
